(19) United States
(12) Patent Application Publication
(10) Pub. No.: US 2025/0312951 A1
(43) Pub. Date: Oct. 9, 2025

(54) MOLD, MANUFACTURING METHOD, FILM FORMING METHOD, ARTICLE MANUFACTURING METHOD AND IMPRINT APPARATUS

(71) Applicant: CANON KABUSHIKI KAISHA, Tokyo (JP)

(72) Inventors: HINAKO MATSUSHIMA, Tochigi (JP); TOSHIKI ITO, Kanagawa (JP); HIDEKI IMAMURA, Tochigi (JP); KEN KATSUTA, Saitama (JP); TETSUJI OKADA, Saitama (JP)

(21) Appl. No.: 19/170,500

(22) Filed: Apr. 4, 2025

(30) Foreign Application Priority Data
Apr. 9, 2024 (JP) 2024-062921

(51) Int. Cl. B29C 43/36; B29C 33/38; B29C 43/02; G03F 7/00

(52) U.S. Cl. CPC B29C 43/36; B29C 33/3842; B29C 43/021; G03F 7/0002; B29K 2909/08; B29K 2995/0077

(57) ABSTRACT

A mold including a first part made of a material having a first elastic modulus, and a second part made of a material having a second elastic modulus lower than the first elastic modulus, wherein the first part includes a first surface including a mesa portion and a second surface which includes a concave portion, the second part includes a base portion including a third surface combined to the mesa portion and a fourth surface, and a pattern portion that includes a convex portion defining a pattern, a thickness of the base portion defined by a distance between the third surface and the fourth surface is not less than 0.1 μm and not more than 10 μm, and the mold includes an inorganic film that covers the fourth surface of the base portion and the convex portion of the pattern portion.

### BACKGROUND OF THE INVENTION

### Field of the Invention

The present invention relates to a mold, a manufacturing method, a film forming method, an article manufacturing method and an imprint apparatus.

### Description of the Related Art

As requirements of miniaturization are increasing for optical members, recording media, semiconductor devices, and MEMS, an imprint technique (optical imprint technique) has received a great deal of attention as a microfabrication technique. In the imprint technique, a curable composition is cured in a state in which a mold with a fine concave-convex pattern formed on the surface is in contact with the curable composition arranged (supplied or applied) onto a substrate. Thus, the pattern of the mold is transferred to the cured film of the curable composition, thereby forming the pattern on the substrate. According to the imprint technique, it is possible to form, on a substrate, a fine pattern (structure) on a several nanometer order.

A master mold used in the imprint technique is very expensive because a fine pattern is formed on the surface of silicon, silica glass, a metal, or the like by precision machining. Hence, Japanese Patent No. 5139421 proposes a technique of manufacturing a replica mold by transferring the fine pattern of the master mold to a mold base material (for example, silica glass) by imprint processing (replica imprint) and etching processing. The replica mold is used in imprint processing (device imprint) for manufacturing various kinds of devices.

When manufacturing a semiconductor device, a foreign substance of about 0.1 μm to 1 μm may exist on a substrate (device substrate). If device imprint is executed for the substrate with the foreign substance using a replica mold made of silica glass, which is manufactured by the technique disclosed in Japanese Patent No. 5139421, a noncontact region of several mm to several ten mm occurs with respect to the foreign substance as the center. Here, since the noncontact region is a region where a curable composition on the substrate and the replica mold are not in contact, the pattern of the replica mold is not transferred to the noncontact region, and the pattern is not formed. The noncontact region can be reduced by applying a strong force (stamping force) to the replica mold, but the possibility that the pattern of the replica mold is compressed by the foreign substance and broken is high. Note that to suppress an increase of cost caused by breakage of the replica mold, the replica mold may be formed using a relatively inexpensive organic material. In this case, however, there is concern that a curable composition adheres to the replica mold.

### SUMMARY OF THE INVENTION

The present invention provides a new technique concerning a mold.

According to one aspect of the present invention, there is provided a mold including a first part made of a material having a first elastic modulus, and a second part made of a material having a second elastic modulus lower than the first elastic modulus, and used for imprint lithography, wherein the first part includes a first surface including a mesa portion protruding from a plane, and a second surface on an opposite side of the first surface, which includes a concave portion, the second part includes a base portion including a third surface combined to the mesa portion and a fourth surface on an opposite side of the third surface, and a pattern portion that includes a convex portion protruding from the fourth surface and defines a pattern, a thickness of the base portion defined by a distance between the third surface and the fourth surface is not less than 0.1 μm and not more than 10 μm, and the mold includes an inorganic film that covers the fourth surface of the base portion and the convex portion of the pattern portion.

Further aspects of the present invention will become apparent from the following description of exemplary embodiments with reference to the attached drawings.

### BRIEF DESCRIPTION OF THE DRAWINGS

FIG. 1 is a view for describing configurations of a replica mold according to an aspect of the present invention;

FIG. 2 is a view for describing configurations of a replica mold according to an aspect of the present invention;

FIG. 3 is a view for describing configurations of a replica mold according to an aspect of the present invention;

FIG. 4 is a view for describing configurations of a replica mold according to an aspect of the present invention;

FIGS. 5A to 5H are views for describing a manufacturing method for manufacturing a replica mold;

FIGS. 6A and 6B are views for describing a manufacturing method for manufacturing a replica mold;

FIGS. 7A to 7E are views illustrating the configurations of replica molds according to Example 1 and Comparative Examples 1, 2, 3, and 4;

FIGS. 8A to 8D are views for describing a contact step of imprint processing;

FIG. 9 is a view for describing an analysis model of the behavior of the replica mold of following a foreign substance;

FIG. 10 is a view for describing the difference of the behavior of the replica mold of following a foreign substance between Example 1 and Comparative Example 2;

FIG. 11 is a schematic view illustrating configurations of an imprint apparatus according to an aspect of the present invention; and

FIGS. 12A to 12F are views for describing an article manufacturing method.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

### [Replica Mold]

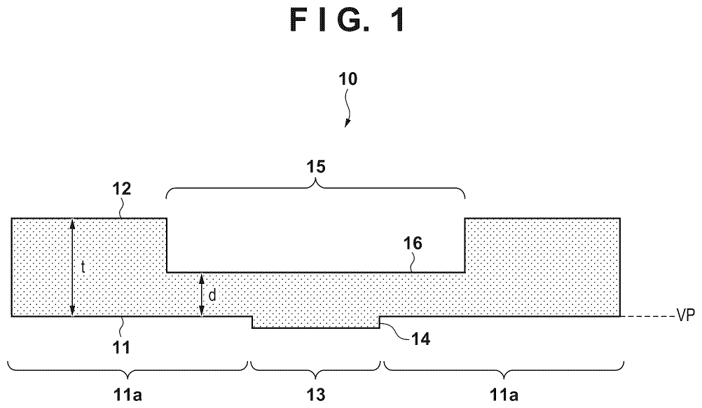

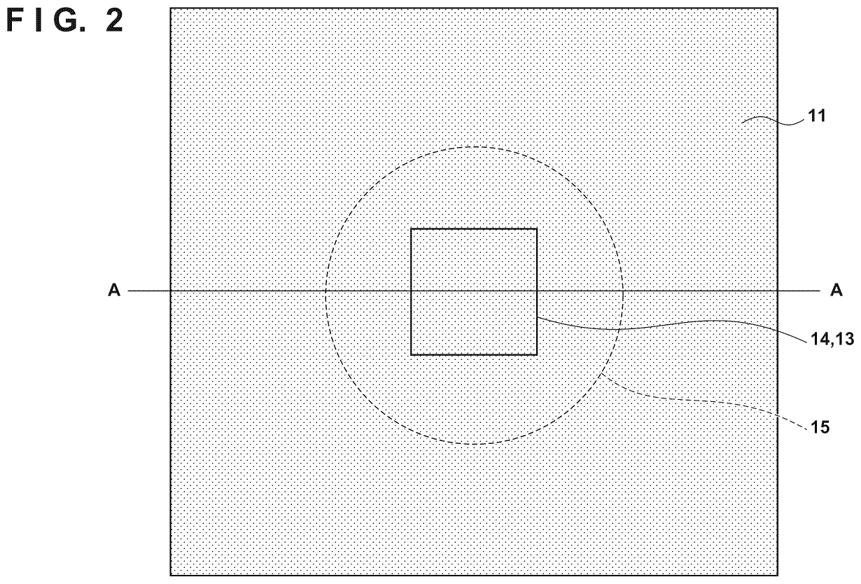

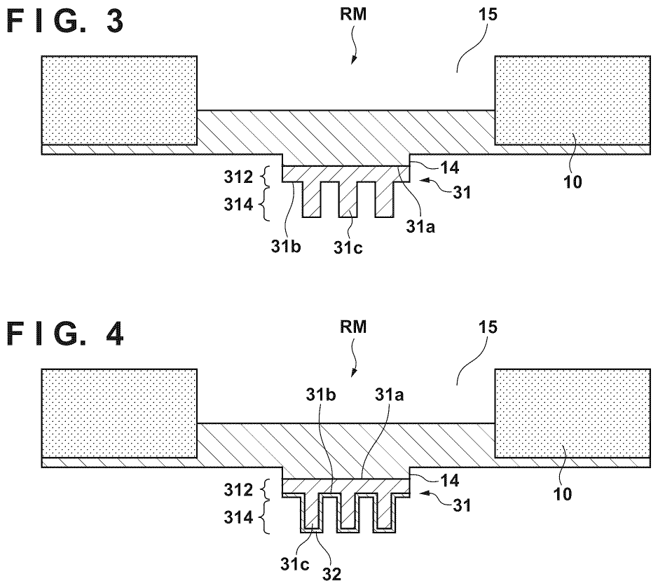

FIGS. 1, 2, 3, and 4 are views for describing the configuration of a replica mold RM according to an aspect of the present invention. The replica mold RM is a mold (a mold, a template, or an original) used in imprint lithography (an imprint apparatus employing an imprint technique) and is embodied as a replica mold manufactured from a master mold in this embodiment. As shown in FIG. 4, the replica mold RM includes a high elastic modulus part 10 (first part) made of a high elastic modulus material having a first elastic modulus, a low elastic modulus part 31 (second part) made of a low elastic modulus material having a second elastic modulus lower than the first elastic modulus, and an inorganic film 32 containing an inorganic element. FIG. 1 is a sectional view schematically showing the high elastic modulus part 10, and FIG. 2 is a plan view schematically showing the high elastic modulus part 10. Note that a sectional view taken along a line A-A in FIG. 2 is FIG. 1. FIG. 3 is a sectional view schematically showing the high elastic modulus part 10 and the low elastic modulus part 31. FIG. 4 is a sectional view schematically showing the replica mold RM having the high elastic modulus part 10, the low elastic modulus part 31, and the inorganic film 32.

The high elastic modulus part 10 (high elastic modulus material) has an elastic modulus of 20 GPa or more, preferably has an elastic modulus of 50 GPa or more, and particularly preferably has an elastic modulus of 70 GPa or more. The higher the elastic modulus (first elastic modulus) of the high elastic modulus part 10 is, the more a stamping force is transmitted to the low elastic modulus part 31. The low elastic modulus part 31 (low elastic modulus material) has an elastic modulus of 10 GPa or less, preferably has an elastic modulus of 3 GPa or less, and particularly preferably has an elastic modulus of 1 GPa or less. The lower the elastic modulus (second elastic modulus) of the low elastic modulus part 31 is, the higher the followability to a foreign substance existing on a transfer target to transfer the pattern of the replica mold RM is.

As shown in FIGS. 1 and 2, the high elastic modulus part 10 is made of a replica base material that is the base material of the replica mold. As shown in FIG. 1, the high elastic modulus part 10 includes a first surface 11 including a plane 11a, and a second surface 12 on the opposite side of the first surface 11. The first surface 11 includes a mesa portion 14 (convex portion) that protrudes from the plane 11a to the opposite side of the second surface 12 to form a convex shape, that is, a step structure higher than the periphery. The mesa portion 14 is formed at the center portion of the first surface 11 and defines a pattern region 13 where a pattern corresponding to a pattern to be transferred to the transfer target is formed. The mesa portion 14 has an area, for example, 0.5% or more and 10% or less the area of the first surface 11. The mesa portion 14 has a height more than 0 μm and 1,000 μm or less. For example, the mesa portion 14 has a height of 1 μm or more and 1,000 μm or less from the first surface 11. On the other hand, the second surface 12 includes a concave portion 15 (core out) having a concave shape on the side of the first surface 11, as shown in FIG. 1. The concave portion 15 is formed at the center portion of the second surface 12 such that a distance d between the plane 11a of the first surface 11 and the bottom surface of the concave portion 15 (that is, the thickness of the bottom portion) is, for example, 0.1 mm or more and 3 mm or less. As shown in FIGS. 1 and 2, the concave portion 15 is formed in the second surface 12 such that a region (a circle indicated by a dotted line) formed by orthogonally projecting the concave portion 15 to a virtual plane VP parallel to the first surface 11, more specifically, the plane 11a overlaps the mesa portion 14 (pattern region 13) formed on the first surface 11. Furthermore, the concave portion 15 is formed in the second surface 12 such that the region formed by orthogonally projecting the concave portion 15 to the virtual plane VP has an area larger than the area of the mesa portion 14. In other words, the mesa portion 14 is located in a region inside the outer edge of the region formed by orthogonally projecting the concave portion 15 to the virtual plane VP. Also, the maximum thickness of the high elastic modulus part 10, more specifically, a distance t between the plane 11a of the first surface 11 and a portion of the second surface 12 without the concave portion is 6.35 mm±0.10 mm.

As shown in FIG. 3, the low elastic modulus part 31 includes a base portion 312 including a third surface 31a combined to the mesa portion 14 of the high elastic modulus part 10 and a fourth surface 31b on the opposite side of the third surface 31a, and a pattern portion 314 that includes convex portions 31c protruding from the fourth surface 31b and defines the pattern. The low elastic modulus part 31 is combined to (formed on) the first surface 11 of the high elastic modulus part 10, more specifically, the mesa portion 14 (pattern region 13) formed on the first surface 11 via the third surface 31a. When forming the low elastic modulus part 31 on the mesa portion 14, an imprint method is used. More specifically, by the imprint method, the base portion 312 is formed on the mesa portion 14, and the pattern portion 314 (convex portions 31c) that defines the pattern corresponding to the pattern to be transferred to the transfer target is formed. In this embodiment, the thickness of the base portion 312, which is defined by the distance between the third surface 31a and the fourth surface 31b of the base portion 312, is 0.1 μm or more and 10 μm or less.

The low elastic modulus part 31 is formed by, for example, a curable composition (A) for a replica mold. The curable composition (A) will be described later in detail. In this embodiment, a nonvolatile composition (A′) in a state in which a solvent is removed by volatilization or the like from the curable composition (A) is photopolymerized, thereby forming the low elastic modulus part 31.

As shown in FIG. 4, the inorganic film 32 is a film that covers the low elastic modulus part 31, more specifically, that covers the fourth surface 31b of the base portion 312 of the low elastic modulus part 31 and the convex portions 31c of the pattern portion 314 of the low elastic modulus part 31.

### [Replica Mold Manufacturing Method]

A manufacturing method of manufacturing the replica mold RM includes a first step of forming the low elastic modulus part 31 on the mesa portion 14 formed on the first surface 11 of the high elastic modulus part 10 using an imprint method, and a second step of forming the inorganic film 32 that covers the low elastic modulus part 31 using a deposition method.

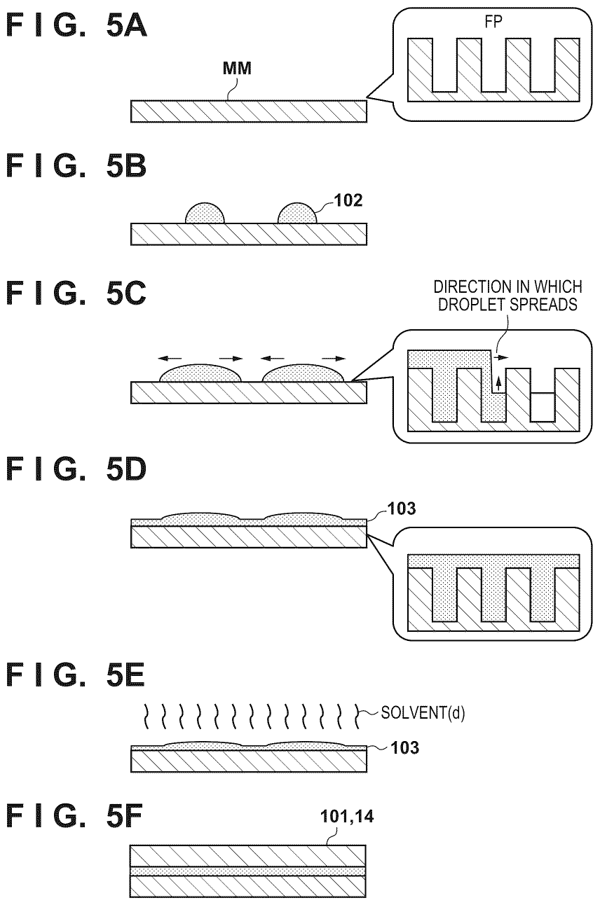

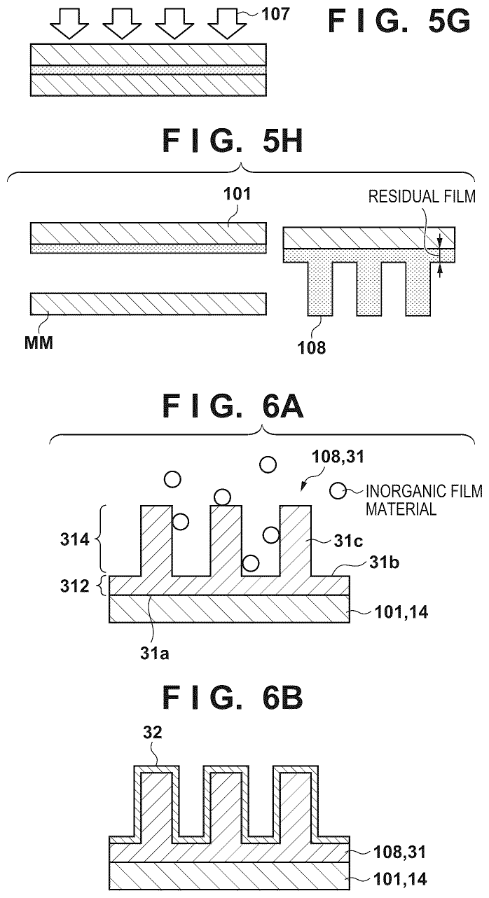

The first step (imprint method) includes a preparation step of a master mold, a preparation step of the curable composition (A) that is a low elastic modulus material, an arranging step, a waiting step, a contact step, a curing step, and a mold release step. The manufacturing method of manufacturing the replica mold RM, more specifically, the first step of forming the low elastic modulus part 31 will be described below with reference to FIGS. 5A to 5H.

### <Preparation Step of Master Mold>

As schematically shown in FIG. 5A, a master mold MM is prepared. The master mold MM has a fine pattern FP on its surface. The fine pattern FP is an inverted pattern obtained by inverting (the concave-convex structure of) a pattern to be formed on the replica mold RM. As the master mold MM, a mold made of a non-light transmitting material or a mold made of a light transmitting material can be used. Examples of the mold base material of the mold made of a non-light transmitting material are a silicon wafer, nickel, copper, stainless steel, titanium, SiC, and mica. Examples of the mold base material of the mold made of a light transmitting material are glass such as silica glass, polydimethylsiloxane, cyclic polyolefin, polycarbonate, polyethylene terephthalate, and transparent fluororesin. The mold made of a light transmitting material may be made of a plurality of materials. Note that as the mold base material of the master mold MM, a silicon wafer or a quartz wafer is preferable because materials having high quality and high use result in the semiconductor industry are available.

The fine pattern FP of the master mold MM is formed using, for example, a micropatterning technique such as an electron beam lithography technique. The fine pattern FP formed on the master mold MM has a height of, for example, 4 nm or more and 200 nm or less. As the height of the fine pattern FP of the master mold MM decreases, it becomes possible to decrease the force necessary for releasing the master mold MM from the cured film of a curable composition (A), that is, the mold release force in the mold release step. Hence, it is possible to decrease the number of mold release defects remaining in the master mold MM because the pattern of the curable composition (A) is torn off. Also, in some cases, the pattern of the curable composition (A) elastically deforms due to the impact when the master mold MM is released, and adjacent pattern elements come in contact with each other and adhere to each other or break each other. Note that to avoid these inconveniences, it is advantageous to make the height of pattern elements be about twice or less the width of the pattern elements (make the aspect ratio be 2 or less). On the other hand, if the height of pattern elements is too small, the processing accuracy of the mold base material decreases.

A surface treatment can also be performed on the master mold MM before performing the arranging step, in order to improve the detachability of the master mold MM with respect to the curable composition (A). An example of this surface treatment is to form a mold release agent layer by coating the surface of the master mold MM with a mold release agent. Examples of the mold release agent to be applied on the surface of the master mold MM are a silicon-based mold release agent, a fluorine-based mold release agent, a hydrocarbon-based mold release agent, a polyethylene-based mold release agent, a polypropylene-based mold release agent, a paraffine-based mold release agent, a montane-based mold release agent, and a carnauba-based mold release agent. It is also possible to suitably use a commercially available coating-type mold release agent such as Optool® DSX manufactured by Daikin. Note that it is possible to use one type of a mold release agent alone, or use two or more types of mold release agents together. Of the mold release agents described above, fluorine-based and hydrocarbon-based mold release agents are particularly favorable.

<Preparation Step of Curable Composition (a)>

The curable composition (A) as a low elastic modulus material is prepared. The curable composition (A) is a composition containing at least a polymerizable compound (a), and a photopolymerization initiator (b). The curable composition (A) may be a composition further containing a nonpolymerizable compound (c), and a solvent (d) within the scope not impairing the effect of the present invention. The curable composition (A) is a curable composition for inkjet.

In this specification, the polymerizable compound (a) is a compound that reacts with a polymerizing factor (for example, a radical) generated from a polymerization initiator (b), and forms a film made of a polymer compound by a chain reaction (polymerization reaction).

An example of the polymerizable compound as described above is a radical polymerizable compound. The polymerizable compound (a) can be formed by only one type of a polymerizable compound, and can also be formed by a plurality of types (one or more types) of polymerizable compounds.

Examples of the radical polymerizable compound are a (meth)acrylic compound, a styrene-based compound, a vinyl-based compound, an allylic compound, a fumaric compound, and a maleic compound.

The (meth)acrylic compound is a compound having one or more acryloyl groups or methacryloyl groups. Examples of a monofunctional (meth)acrylic compound having one acryloyl group or methacryloyl group are as follows, but the compound is not limited to these examples.

Phenoxyethyl (meth)acrylate, phenoxy-2-methylethyl (meth)acrylate, phenoxyethoxyethyl (meth)acrylate, 3-phenoxy-2-hydroxypropyl (meth)acrylate, 2-phenylphenoxyethyl (meth)acrylate, 4-phenylphenoxyethyl (meth)acrylate, 3-(2-phenylphenyl)-2-hydroxypropyl (meth)acrylate, (meth)acrylate of EO-modified p-cumylphenol, 2-bromophenoxyethyl (meth)acrylate, 2,4-dibromophenoxyethyl (meth)acrylate, 2,4,6-tribromophenoxyethyl (meth)acrylate, EO-modified phenoxy (meth)acrylate, PO-modified phenoxy (meth)acrylate, polyoxyethylenenonylphenylether (meth)acrylate, isobornyl (meth)acrylate, 1-adamantyl (meth)acrylate, 2-methyl-2-adamantyl (meth)acrylate, 2-ethyl-2-adamantyl (meth)acrylate, bornyl (meth)acrylate, tricyclodecanyl (meth)acrylate, dicyclopentanyl (meth)acrylate, dicyclopentenyl (meth)acrylate, cyclohexyl (meth)acrylate, 4-butylcyclohexyl(meth)acrylate, acryloylmorpholine, 2-hydroxyethyl (meth)acrylate, 2-hydroxypropyl (meth)acrylate, 2-hydroxybutyl (meth)acrylate, methyl (meth)acrylate, ethyl (meth)acrylate, propyl (meth)acrylate, isopropyl (meth)acrylate, butyl (meth)acrylate, amyl (meth)acrylate, isobutyl (meth)acrylate, t-butyl (meth)acrylate, pentyl (meth)acrylate, isoamyl (meth)acrylate, hexyl (meth)acrylate, heptyl (meth)acrylate, octyl (meth)acrylate, isooctyl (meth)acrylate, 2-ethylhexyl (meth)acrylate, nonyl (meth)acrylate, decyl (meth)acrylate, isodecyl (meth)acrylate, undecyl (meth)acrylate, dodecyl (meth)acrylate, lauryl (meth)acrylate, stearyl (meth)acrylate, isostearyl (meth)acrylate, benzyl (meth)acrylate, tetrahydrofurfuryl (meth)acrylate, butoxyethyl (meth)acrylate, ethoxydiethyleneglycol (meth)acrylate, polyethyleneglycol mono(meth)acrylate, polypropyleneglycol mono(meth)acrylate, methoxyethyleneglycol (meth)acrylate, ethoxyethyl (meth)acrylate, methoxypolyethyleneglycol (meth)acrylate, methoxypolypropyleneglycol (meth)acrylate, diacetone (meth)acrylamide, isobutoxymethyl (meth)acrylamide, N,N-dimethyl (meth)acrylamide, t-octyl (meth)acrylamide, dimethylaminoethyl (meth)acrylate, diethylaminoethyl (meth)acrylate, 7-amino-3,7-dimethyloctyl (meth)acrylate, N,N-diethyl (meth)acrylamide, N,N-dimethylaminopropyl (meth)acrylamide, 1- or 2-naphthyl (meth)acrylate, 1- or 2-naphthylmethyl (meth)acrylate, 3- or 4-phenoxybenzyl (meth)acrylate, cyanobenzyl (meth)acrylate, naphthalene methyl (meth)acrylate.

Examples of commercially available products of the above-described monofunctional (meth)acrylic compounds are as follows, but the products are not limited to these examples.

ARONIX® M101, M102, M110, M111, M113, M117, M5700, TO-1317, M120, M150, and M156 (manufactured by TOAGOSEI); MEDOL10, MIBDOL10, CHDOL10, MMDOL30, MEDOL30, MIBDOL30, CHDOL30, LA, IBXA, 2-MTA, HPA, and Viscoat #150, #155, #158, #190, #192, #193, #220, #2000, #2100, and #2150 (manufactured by OSAKA ORGANIC CHEMICAL INDUSTRY); Light Acrylate BO-A, EC-A, DMP-A, THF-A, HOP-A, HOA-MPE, HOA-MPL, PO-A, P-200A, NP-4EA, NP-8EA, Epoxy Ester M-600A, POB-A, and OPP-EA (manufactured by KYOEISHA CHEMICAL); KAYARAD® TC-110S, R-564, and R-128H (manufactured by NIPPON KAYAKU); NK Ester AMP-10G, AMP-20G, and A-LEN-10 (manufactured by SHIN-NAKAMURA CHEMICAL); FA-511A, 512A, and 513A (manufactured by Hitachi Chemical); PHE, CEA, PHE-2, PHE-4, BR-31, BR-31M, and BR-32 (manufactured by DKS); VP (manufactured by BASF); ACMO, DMAA, and DMAPAA (manufactured by Kohjin); and HRD-01 (manufactured by NIPPON SHOKUBAI).

Examples of a polyfunctional (meth)acrylic compound having two or more acryloyl groups or methacryloyl groups are as follows, but the compound is not limited to these examples.

Trimethylolpropane di(meth)acrylate, trimethylolpropane tri(meth)acrylate, EO-modified trimethylolpropane tri(meth)acrylate, PO-modified trimethylolpropane tri(meth)acrylate, EO- and PO-modified trimethylolpropane tri(meth)acrylate, dimethylol tricyclodecane di(meth)acrylate, pentaerythritol tri(meth)acrylate, pentaerythritol tetra(meth)acrylate, ethylene glycol di(meth)acrylate, tetraethylene glycol di(meth)acrylate, polyethylene glycol di(meth)acrylate, polypropylene glycol di(meth)acrylate, 1,4-butanediol di(meth)acrylate, 1,6-hexanediol di(meth)acrylate, neopentyl glycol di(meth)acrylate, 1,9-nonanediol di(meth)acrylate, 1,10-decanediol di(meth)acrylate, 1,3-adamantanedimethanol di(meth)acrylate, tris(2-hydoxyethyl)isocyanurate tri(meth)acrylate, tris(acryloyloxy)isocyanurate, bis(hydroxymethyl)tricyclodecane di(meth)acrylate, dipentaerythritol penta(meth)acrylate, dipentaerythritol hexa(meth)acrylate, EO-modified 2,2-bis(4-((meth)acryloxy)phenyl)propane, PO-modified 2,2-bis(4-((meth)acryloxy)phenyl)propane, EO- and PO-modified 2,2-bis(4-((meth)acryloxy)phenyl)propane, o-, m-, or p-benzene di(meth)acrylate, and o-, m-, or p-xylylene di(meth)acrylate.

Examples of commercially available products of the above-described polyfunctional (meth)acrylic compounds are as follows, but the products are not limited to these examples.

Yupimer® UV SA1002 and SA2007 (manufactured by Mitsubishi Chemical); Viscoat #195, #230, #215, #260, #335HP, #295, #300, #360, #700, GPT, and 3PA (manufactured by OSAKA ORGANIC CHEMICAL INDUSTRY); Light Acrylate 4EG-A, 9EG-A, NP-A, DCP-A, BP-4EA, BP-4PA, TMP-A, PE-3A, PE-4A, and DPE-6A (manufactured by KYOEISHA CHEMICAL); KAYARAD® PET-30, TMPTA, R-604, DPHA, DPCA-20, -30, -60, and -120, HX-620, D-310, and D-330 (manufactured by NIPPON KAYAKU); ARONIX® M208, M210, M215, M220, M240, M305, M309, M310, M315, M325, and M400 (manufactured by TOAGOSEI); Ripoxy® VR-77, VR-60, and VR-90 (manufactured by Showa Highpolymer); OGSOL EA-0200 and OGSOL EA-0300 (manufactured by Osaka Gas Chemicals); and SR295 and SR355 (manufactured by Sartomer).

Note that in the above-described compound county, (meth)acrylate means acrylate or methacrylate having an alcohol residue equal to acrylate. A (meth)acryloyl group means an acryloyl group or a methacryloyl group having an alcohol residue equal to the acryloyl group. EO indicates ethylene oxide, and an EO-modified compound A indicates a compound in which a (meth)acrylic acid residue and an alcohol residue of a compound A bond via the block structure of an ethylene oxide group. Also, PO indicates a propylene oxide, and a PO-modified compound B indicates a compound in which a (meth)acrylic acid residue and an alcohol residue of a compound B bond via the block structure of a propylene oxide group.

Practical examples of the styrene-based compound are as follows, but the compound is not limited to these examples.

Alkylstyrene such as styrene, 2,4-dimethyl-α-methylstyrene, o-methylstyrene, m-methylstyrene, p-methylstyrene, 2,4-dimethylstyrene, 2,5-dimethylstyrene, 2,6-dimethylstyrene, 3,4-dimethylstyrene, 3,5-dimethylstyrene, 2,4,6-trimethylstyrene, 2,4,5-trimethylstyrene, pentamethylstyrene, o-ethylstyrene, m-ethylstyrene, p-ethylstyrene, diethylstyrene, triethylstyrene, propylstyrene 2,4-diisopropylstyrene, butylstyrene, hexylstyrene, heptylstyrene, and octylstyrene; styrene halide such as fluorostyrene, o-chlorostyrene, m-chlorostyrene, p-chlorostyrene, o-bromostyrene, m-bromostyrene, p-bromostyrene, dibromostyrene, and iodostyrene; and a compound having a styryl group as a polymerizable functional group, such as nitrostyrene, acetylstyrene, o-methoxystyrene, m-methoxystyrene, p-methoxystyrene, o-hydroxystyrene, m-hydroxystyrene, p-hydroxystyrene, 2-vinylbiphenyl, 3-vinylbiphenyl, 4-vinylbiphenyl, 1-vinylnaphthalene, 2-vinylnaphthalene, 4-vinyl-p-terphenyl, 1-vinylanthracene, α-methylstyrene, o-isopropenyltoluene, m-isopropenyltoluene, p-isopropenyltoluene, 2,3-dimethyl-α-methylstyrene, 3,5-dimethyl-α-methylstyrene, p-isopropyl-α-methylstyrene, α-ethylstyrene, α-chlorostyrene, divinylbenzene, diisopropylbenzene, and divinylbiphenyl.

Practical examples of the vinyl-based compound are as follows, but the compound is not limited to these examples.

Vinylpyridine, vinylpyrrolidone, vinylcarbazole, vinyl acetate, and acrylonitrile; conjugated diene monomers such as butadiene, isoprene, and chloroprene; vinyl halide such as vinyl chloride and vinyl bromide; a compound having a vinyl group as a polymerizable functional group, for example, vinylidene halide such as vinylidene chloride, vinyl ester of organic carboxylic acid and its derivative (for example, vinyl acetate, vinyl propionate, vinyl butyrate, vinyl benzoate, and divinyl adipate), and (meth)acrylonitrile.

Note that in this specification, (meth)acrylonitrile is a general term for acrylonitrile and methacrylonitrile.

Examples of the allylic compound are as follows, but the compound is not limited to these examples.

Allyl acetate, allyl benzoate, diallyl adipate, diallyl terephthalate, diallyl isophthalate, and diallyl phthalate.

Examples of the fumaric compound are as follows, but the compound is not limited to these examples.

Dimethyl fumarate, diethyl fumarate, diisopropyl fumarate, di-sec-butyl fumarate, diisobutyl fumarate, di-n-butyl fumarate, di-2-ethylhexyl fumarate, and dibenzyl fumarate.

Examples of the maleic compound are as follows, but the compound is not limited to these examples.

Dimethyl maleate, diethyl maleate, diisopropyl maleate, di-sec-butyl maleate, diisobutyl maleate, di-n-butyl maleate, di-2-ethylhexyl maleate, and dibenzyl maleate.

Other examples of the radical polymerizable compound are as follows, but the compound is not limited to these examples.

Dialkylester of itaconic acid and its derivative (for example, dimethyl itaconate, diethyl itaconate, diisopropyl itaconate, di-sec-butyl itaconate, diisobutyl itaconate, di-n-butyl itaconate, di-2-ethylhexyl itaconate, and dibenzyl itaconate), an N-vinylamide derivative of organic carboxylic acid (for example, N-methyl-N-vinylacetamide), and maleimide and its derivative (for example, N-phenylmaleimide and N-cyclohexylmaleimide).

If the polymerizable compound (a) is formed by a plurality of types of compounds having one or more polymerizable functional groups, both a monofunctional polymerizable compound and a polyfunctional polymerizable compound are preferably included. The ratio of the polyfunctional polymerizable compound in the polymerizable compound (a) is preferably 20 wt % or more, more preferably 25 wt % or more, and particularly preferably 40 wt % or more. This is because if a monofunctional compound and a polyfunctional compound are combined, a cured film having well-balanced performance, for example, a high mechanical strength, a high dry etching resistance, and a high heat resistance can be obtained.

In this embodiment, a few milliseconds to a few hundreds of seconds are required until a plurality of droplets of the curable composition (A) discretely arranged on a replica base material (substrate) combine with adjacent droplets and form a practically continuous liquid film, so a waiting step (to be described later) is necessary. In this waiting step, the solvent (d) is volatilized, but the polymerizable compound (a) must not be volatilized. Accordingly, the boiling points of one or more types of polymerizable compounds included in the polymerizable compound (a) at normal pressure are preferably 250° C. or more, more preferably 300° C. or more, and further preferably 350° C. or more. Also, to obtain a high dry etching resistance and a high heat resistance, the cured film of the curable composition (A) preferably contains at least a compound having a cyclic structure such as an aromatic structure, an aromatic heterocyclic structure, or an alicyclic structure. Note that the normal pressure is 1 atm (atmospheric pressure).

The boiling point of the polymerizable compound (a) is substantially correlated with the molecular weight. Therefore, the molecular weights of one or more types of polymerizable compounds included in the polymerizable compound (a) are preferably 200 or more, more preferably 240 or more, and further preferably 250 or more. However, even when the molecular weight is 200 or less, the compound is preferably usable as the polymerizable compound (a) of the present invention if the boiling point is 250° C. or more. As described above, the boiling points of one or more types of polymerizable compounds included in the polymerizable compound (a) are preferably 250° C. or more at normal pressure.

In addition, the vapor pressure at 80° C. of the polymerizable compound (a) is preferably 0.001 mmHg or less. If the polymerizable compound (a) includes one or more types of polymerizable compounds, the vapor pressures of the one or more types of polymerizable compounds at 80° C. are preferably 0.001 mmHg or less. This is so because, although it is favorable to heat the curable composition (A) when accelerating volatilization of the solvent (d) (to be described later), it is necessary to suppress volatilization of the polymerizable compound (a) during heating.

Note that the boiling point and the vapor pressure of each of various kinds of organic compounds at normal pressure can be calculated by, for example, Hansen Solubility Parameters in Practice (HSPiP) 5th Edition. 5.3.04.

It is known that a dry etching rate V of an organic compound, a number N of all atoms in the organic compound, a number N_{C} of all carbon atoms in a composition, and a number No of all oxygen atoms in the composition have a relationship of equation (1) below.

$$V ∝ N / ( {N}_{C} - {N}_{o} ) \qquad ( 1 )$$

where N/(N_{C}−N_{O}) is also called “Ohnishi Parameter” (to be referred to as “OP” hereinafter). For example, the specification of US-2020-0286740 has disclosed a technique of obtaining a photocurable composition having a high dry etching resistance by using a polymerizable compound having a small OP.

Equation (1) indicates that an organic compound having many oxygen atoms in a molecule or having few aromatic ring structures or alicyclic structures has a large OP and a high dry etching rate.

In the curable composition (A) according to the present invention, the OP of the polymerizable compound (a) is 1.80 or more and 4.00 or less. The OP of the polymerizable compound (a) is more preferably 2.00 or more and 3.50 or less, and particularly preferably 2.40 or more and 3.00 or less. When the OP of the polymerizable compound (a) is 4.00 or less, the cured film of the curable composition (A) has a high dry etching resistance. Also, when the OP of the polymerizable compound (a) is 1.80 or more, the cured film of the curable composition (A) can easily be removed when the underlayer is processed by using the cured film of the curable composition (A). When the polymerizable compound (a) is formed by a plurality of types polymerizable compounds a₁, a₂, . . . , aₙ, the OP is calculated as a weighted average value (molar fraction weighted average value) based on the molar fraction as indicated by equation (2) below. If the polymerizable compound (a) contains one or more types of polymerizable compounds, the OP of the polymerizable compound (a) is calculated as the molar fraction weighted average value of an N/(Nc−No) value of each molecule of the one or more types of polymerizable compounds.

$$OP = {\sum }_{i = n} {n}_{i} {OP}_{i} = {n}_{1} {OP}_{1} + {n}_{2} {OP}_{2} + ⋯ + {n}_{n} {OP}_{n} \qquad ( 2 )$$

where OPₙ is the OP of the component aₙ, and nₙ is the molar fraction occupied by the component aₙ in the entire polymerizable compound (a).

To set the OP of the polymerizable compound (a) to 1.80 or more and 2.70 or less, a polymerizable compound (a-1) having two or more cyclic structures, in which at least one of the cyclic structures is an aromatic structure or an aromatic heterocyclic structure, is preferably contained at least as the polymerizable compound (a).

The polymerizable compound (a) according to the present invention may contain a polymerizable compound (a-1) having an aromatic structure, an aromatic heterocyclic structure, or an alicyclic structure. Also, the ratio of the polymerizable compound (a-1) in the polymerizable compound (a) is preferably 65 wt % or more. When the ratio of the polymerizable compound (a-1) is 65 wt % or more, the OP can be suppressed to 2.70 or less.

Examples of the cyclic structure are an aromatic structure, an aromatic heterocyclic structure, and an alicyclic structure.

The carbon number of the aromatic structure is preferably 6 to 22, more preferably 6 to 18, and further preferably 6 to 10. Practical examples of the aromatic ring are as follows.

A benzene ring, a naphthalene ring, an anthracene ring, a phenanthrene ring, a phenalene ring, a fluorene ring, a benzocyclooctene ring, an acenaphthylene ring, a biphenylene ring, an indene ring, an indane ring, a triphenylene ring, a pyrene ring, a chrysene ring, a perylene ring, and a tetrahydronaphthalene ring.

Note that, of the above-described aromatic rings, a benzene ring or a naphthalene ring is preferable, and a benzene ring is more preferable. The aromatic ring can have a structure in which a plurality of rings are connected. Examples are a biphenyl ring and a bisphenyl ring.

The carbon number of the aromatic heterocyclic structure is preferably 1 to 12, more preferably 1 to 6, and further preferably 1 to 5. Practical examples of the aromatic heterocycle are as follows.

A thiophene ring, a furan ring, a pyrolle ring, an imidazole ring, a pyrazole ring, a triazole ring, a tetrazole ring, a thiazole ring, a thiadiazole ring, an oxadiazole ring, an oxazole ring, a pyridine ring, a pyrazine ring, a pyrimidine ring, pyridazine ring, an isoindole ring, an indole ring, an indazole ring, a purine ring, a quinolizine ring, an isoquinoline ring, a quinoline ring, a phthalazine ring, a naphthyridine ring, a quinoxaline ring, a quinazoline ring, a cinnoline ring, a carbazole ring, an acridine ring, a phenazine ring, a phenothiazine ring, a phenoxathiine ring, and a phenoxazine ring.

The carbon number of the alicyclic structure is preferably 3 or more, more preferably 4 or more, and further preferably 6 or more. In addition, the carbon number of the alicyclic structure is preferably 22 or less, more preferably 18 or less, further preferably 6 or less, and still further preferably 5 or less. Practical examples are as follows.

A cyclopropane ring, a cyclobutane ring, a cyclobutene ring, a cyclopentane ring, a cyclohexane ring, a cyclohexene ring, a cycloheptane ring, a cyclooctane ring, a dicyclopentadiene ring, a spirodecane ring, a spirononane ring, a tetrahydro dicyclopentadiene ring, an octahydronaphthalene ring, a decahydronaphthalene ring, a hexahydroindane ring, a bornane ring, a norbornane ring, a norbornene ring, an isobornane ring, a tricyclodecane ring, a tetracyclododecane ring, and an adamantane ring.

Practical examples of the polymerizable compound (a-1) having a boiling point of 250° C. or more are as follows, but the compound is not limited to these examples.

3-phenoxybenzyl acrylate (mPhOBzA, OP=2.54, boiling point=367.4° C., 80° C. vapor pressure=0.0004 mmHg, molecular weight=254.3)

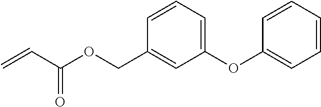 [SMILES: C=CC(=O)OCc1cccc(Oc2ccccc2)c1]

1-naphthyl acrylate (NaA, OP=2.27, boiling point=317° C., 80° C. vapor pressure=0.0422 mmHg, molecular weight=198)

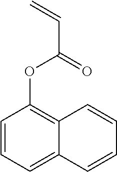

2-phenylphenoxyethyl acrylate (PhPhOEA, OP=2.57, boiling point=364.2° C., 80° C. vapor pressure=0.0006 mmHg, molecular weight=268.3)

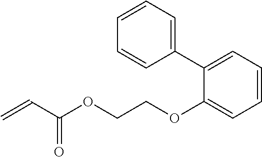 [SMILES: C=CC(=O)OCCOc1ccccc1-c1ccccc1]

1-naphthylmethyl acrylate (Na1MA, OP=2.33, boiling point=342.1° C., 80° C. vapor pressure=0.042 mmHg, molecular weight=212.2)

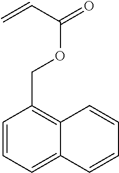 [SMILES: C=CC(=O)OCc1cccc2ccccc12]

2-naphthylmethyl acrylate (Na2MA, OP=2.33, boiling point=342.1° C., 80° C. vapor pressure=0.042 mmHg, molecular weight=212.2)

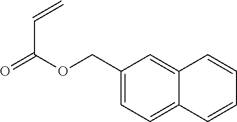 [SMILES: C=CC(=O)OCc1ccc2ccccc2c1]

DPhPA indicated by the formula below (OP=2.38, boiling point=354.5° C., 80° C. vapor pressure=0.0022 mmHg, molecular weight=266.3)

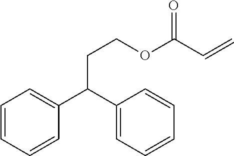 [SMILES: C=CC(=O)OCCC(c1ccccc1)c1ccccc1]

PhBzA indicated by the formula below (OP=2.29, boiling point=350.4° C., 80° C. vapor pressure=0.0022 mmHg, molecular weight=238.3)

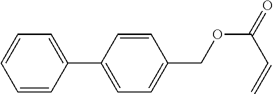 [SMILES: C=CC(=O)OCc1ccc(-c2ccccc2)cc1]

FLMA indicated by the formula below (OP=2.20, boiling point=349.3° C., 80° C. vapor pressure=0.0018 mmHg, molecular weight=250.3)

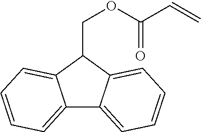 [SMILES: C=CC(=O)OCC1c2ccccc2-c2ccccc21]

ATMA indicated by the formula below (OP=2.13, boiling point=414.9° C., 80° C. vapor pressure=0.0001 mmHg, molecular weight=262.3)

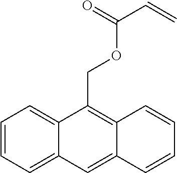 [SMILES: C=CC(=O)OCc1c2ccccc2cc2ccccc12]

DNaMA indicated by the formula below (OP=2.00, boiling point=489.4° C., 80° C. vapor pressure <0.0001 mmHg, molecular weight=338.4)

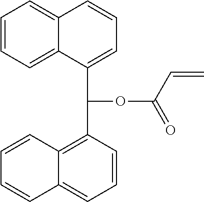 [SMILES: C=CC(=O)OC(c1cccc2ccccc12)c1cccc2ccccc12]

BPh44DA indicated by the formula below (OP=2.63, boiling point=444° C., 80° C. vapor pressure <0.0001 mmHg, molecular weight=322.3)

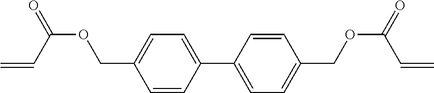 [SMILES: C=CC(=O)OCc1ccc(-c2ccc(COC(=O)C=C)cc2)cc1]

BPh43DA indicated by the formula below (OP=2.63, boiling point=439.5° C., 80° C. vapor pressure <0.0001 mmHg, molecular weight=322.3)

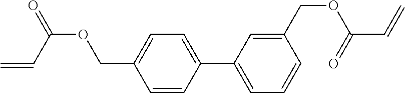 [SMILES: C=CC(=O)OCc1ccc(-c2cccc(COC(=O)C=C)c2)cc1]

DPhEDA indicated by the formula below (OP=2.63, boiling point=410° C., 80° C. vapor pressure <0.0001 mmHg, molecular weight=322.3)

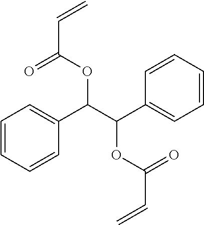 [SMILES: C=CC(=O)OC(c1ccccc1)C(OC(=O)C=C)c1ccccc1]

BPMDA indicated by the formula below (OP=2.68, boiling point=465.7° C., 80° C. vapor pressure <0.0001 mmHg, molecular weight=364.4)

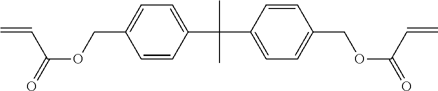 [SMILES: C=CC(=O)OCc1ccc(C(C)(C)c2ccc(COC(=O)C=C)cc2)cc1]

Na13MDA indicated by the formula below (OP=2.71, boiling point=438.8° C., 80° C. vapor pressure <0.0001 mmHg, molecular weight=296.3)

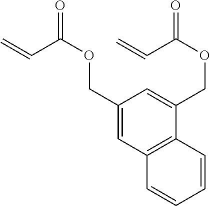 [SMILES: C=CC(=O)OCc1cc(COC(=O)C=C)c2ccccc2c1]

Formula below (a-1-1) (OP=2.40, boiling point=333.4° C., 80° C. vapor pressure=0.0181 mmHg, molecular weight=199.2)

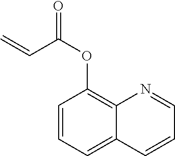

Formula below (a-1-2) (OP=2.40, boiling point=333.4° C., 80° C. vapor pressure=0.0181 mmHg, molecular weight=199.2)

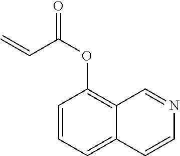

Formula below (a-1-3) (OP=1.86, boiling point=369.5° C., 80° C. vapor pressure=0.0053 mmHg, molecular weight=193.3)

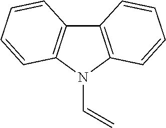

Formula below (a-1-4) (OP=2.85, boiling point=438.8° C., 80° C. vapor pressure <0.0001 mmHg, molecular weight=296.3)

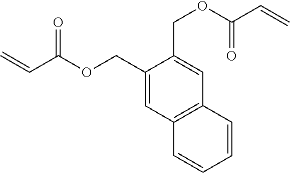 [SMILES: C=CC(=O)OCc1cc2ccccc2cc1COC(=O)C=C]

Formula below (a-1-5) (OP=2.71, boiling point=438.8° C., 80° C. vapor pressure <0.0001 mmHg, molecular weight=296.3)

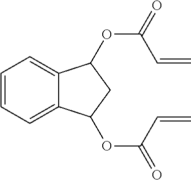 [SMILES: C=CC(=O)OC1CC(OC(=O)C=C)c2ccccc21]

Formula below (a-1-6) (OP=2.87, boiling point=421.0° C., 80° C. vapor pressure <0.0001 mmHg, molecular weight=338.4)

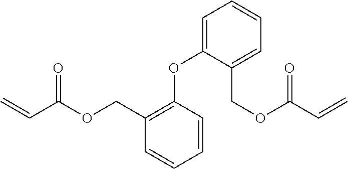 [SMILES: C=CC(=O)OCc1ccccc1Oc1ccccc1COC(=O)C=C]

Formula below (a-1-7) (OP=2.87, boiling point=465.2° C., 80° C. vapor pressure <0.0001 mmHg, molecular weight=338.4

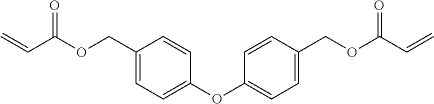 [SMILES: C=CC(=O)OCc1ccc(Oc2ccc(COC(=O)C=C)cc2)cc1]

Formula below (a-1-8) (OP=2.68, boiling point=465.7° C., 80° C. vapor pressure <0.0001 mmHg, molecular weight=364.4)

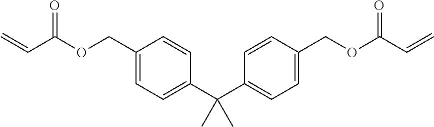 [SMILES: C=CC(=O)OCc1ccc(C(C)(C)c2ccc(COC(=O)C=C)cc2)cc1]

Formula below (a-1-9) (OP=2.50, boiling point=433.1° C., 80° C. vapor pressure <0.0001 mmHg, molecular weight=320.3)

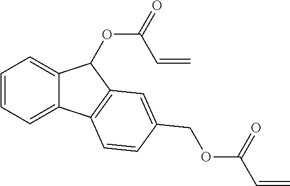 [SMILES: C=CC(=O)OCc1ccc2c(c1)C(OC(=O)C=C)c1ccccc1-2]

Formula below (a-1-10) (OP=2.64, boiling point=468.1° C., 80° C. vapor pressure <0.0001 mmHg, molecular weight=326.4)

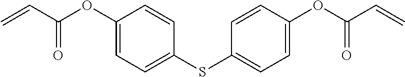 [SMILES: C=CC(=O)Oc1ccc(Sc2ccc(OC(=O)C=C)cc2)cc1]

Formula below (a-1-11) (OP=3.25, boiling point=553.4° C., 80° C. vapor pressure <0.0001 mmHg, molecular weight=358.4)

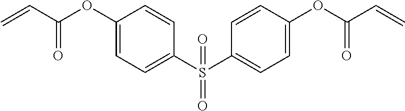 [SMILES: C=CC(=O)Oc1ccc(S(=O)(=O)c2ccc(OC(=O)C=C)cc2)cc1]

Formula below (a-1-12) (OP=2.63, boiling point=443.9° C., 80° C. vapor pressure <0.0001 mmHg, molecular weight=322.4)

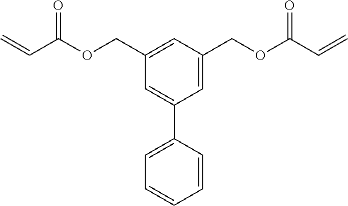 [SMILES: C=CC(=O)OCc1cc(COC(=O)C=C)cc(-c2ccccc2)c1]

Formula below (a-1-13) (OP=2.89, boiling point=509.3° C., 80° C. vapor pressure <0.0001 mmHg, molecular weight=406.4)

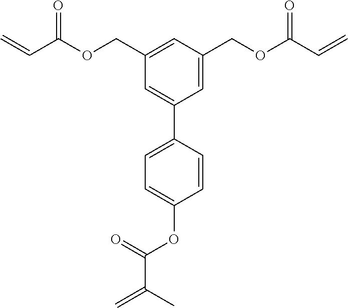 [SMILES: C=CC(=O)OCc1cc(COC(=O)C=C)cc(-c2ccc(OC(=O)C(=C)C)cc2)c1]

Formula below (a-1-14) (OP=2.63, boiling point=450.0° C., 80° C. vapor pressure <0.0001 mmHg, molecular weight=322.4)

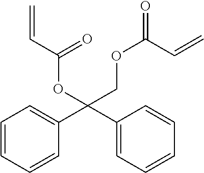 [SMILES: C=CC(=O)OCC(OC(=O)C=C)(c1ccccc1)c1ccccc1]

Formula below (a-1-15) (OP=3.00, boiling point=476.5° C., 80° C. vapor pressure <0.0001 mmHg, molecular weight=366.4)

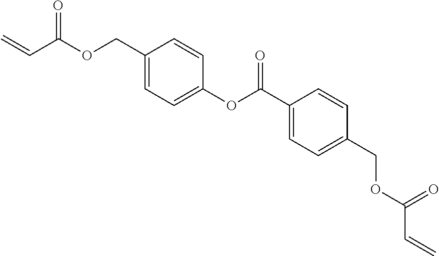 [SMILES: C=CC(=O)OCc1ccc(OC(=O)c2ccc(COC(=O)C=C)cc2)cc1]

Formula below (a-1-16) (OP=2.68, boiling point=447.4° C., 80° C. vapor pressure <0.0001 mmHg, molecular weight=364.4)

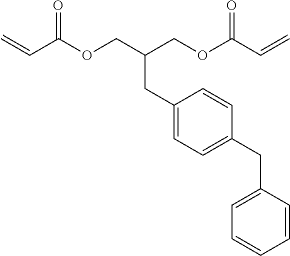 [SMILES: C=CC(=O)OCC(COC(=O)C=C)Cc1ccc(Cc2ccccc2)cc1]

Formula below (a-1-17) (OP=2.36, boiling point=543.8° C., 80° C. vapor pressure <0.0001 mmHg, molecular weight=398.5)

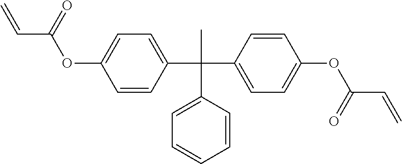 [SMILES: C=CC(=O)Oc1ccc(C(C)(c2ccccc2)c2ccc(OC(=O)C=C)cc2)cc1]

Formula below (a-1-18) (OP=3.27, boiling point=526.9° C., 80° C. vapor pressure <0.0001 mmHg, molecular weight=396.4)

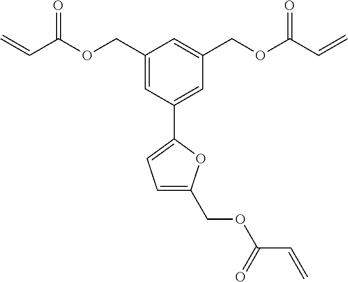 [SMILES: C=CC(=O)OCc1cc(COC(=O)C=C)cc(-c2ccc(COC(=O)C=C)o2)c1]

Formula below (a-1-19) (OP=2.71, boiling point=333.7° C., 80° C. vapor pressure=0.0302 mmHg, molecular weight=244.3)

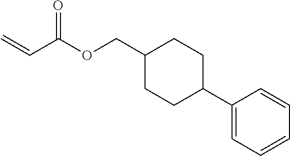 [SMILES: C=CC(=O)OCC1CCC(c2ccccc2)CC1]

Formula below (a-1-20) (OP=2.73, boiling point=333.7° C., 80° C. vapor pressure=0.0134 mmHg, molecular weight=258.3)

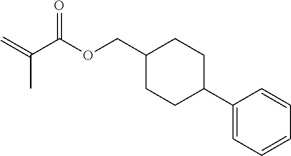 [SMILES: C=C(C)C(=O)OCC1CCC(c2ccccc2)CC1]

Formula below (a-1-21) (OP=2.71, boiling point=319.2° C., 80° C. vapor pressure=0.0566 mmHg, molecular weight=262.3)

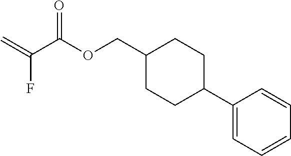 [SMILES: C=C(F)C(=O)OCC1CCC(c2ccccc2)CC1]

Formula below (a-1-22) (OP=2.71, boiling point=336.9° C., 80° C. vapor pressure=0.0055 mmHg, molecular weight=244.3)

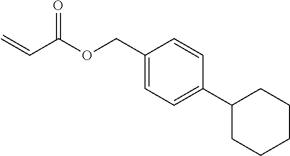 [SMILES: C=CC(=O)OCc1ccc(C2CCCCC2)cc1]

Formula below (a-1-23) (OP=3.00, boiling point=370.9° C., 80° C. vapor pressure=0.0021 mmHg, molecular weight=274.4)

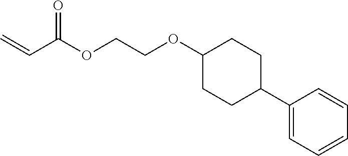 [SMILES: C=CC(=O)OCCOC1CCC(c2ccccc2)CC1]

Formula below (a-1-24) (OP=3.00, boiling point=376.4° C., 80° C. vapor pressure=0.0005 mmHg, molecular weight=274.4)

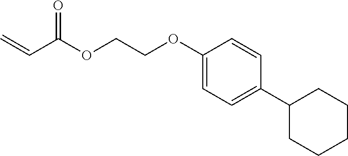 [SMILES: C=CC(=O)OCCOc1ccc(C2CCCCC2)cc1]

Formula below (a-1-25) (OP=3.00, boiling point=379.4° C., 80° C. vapor pressure=0.0002 mmHg, molecular weight=288.4)

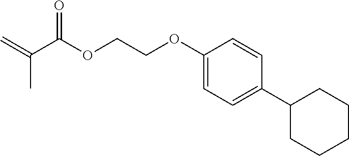 [SMILES: C=C(C)C(=O)OCCOc1ccc(C2CCCCC2)cc1]

Formula below (a-1-26) (OP=2.33, boiling point=360.8° C., 80° C. vapor pressure=0.0006 mmHg, molecular weight=252.3)

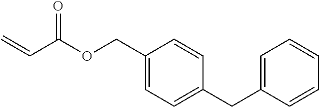 [SMILES: C=CC(=O)OCc1ccc(Cc2ccccc2)cc1]

Formula below (a-1-27) (OP=2.54, boiling point=371.5° C., 80° C. vapor pressure=0.0003 mmHg, molecular weight=254.3)

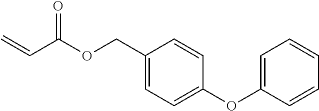 [SMILES: C=CC(=O)OCc1ccc(Oc2ccccc2)cc1]

Formula below (a-1-28) (OP=2.57, boiling point=381.2° C., 80° C. vapor pressure=0.0001 mmHg, molecular weight=268.3)

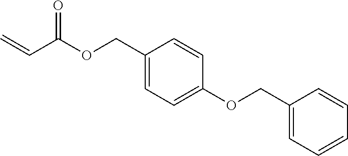 [SMILES: C=CC(=O)OCc1ccc(OCc2ccccc2)cc1]

Formula below (a-1-29) (OP=2.57, boiling point=381.8° C., 80° C. vapor pressure=0.0004 mmHg, molecular weight=268.3)

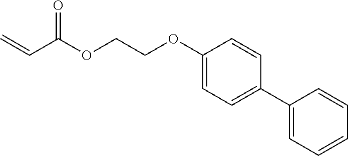 [SMILES: C=CC(=O)OCCOc1ccc(-c2ccccc2)cc1]

Formula below (a-1-30) (OP=2.50, boiling point=487.4° C., 80° C. vapor pressure <0.0001 mmHg, molecular weight=374.4)

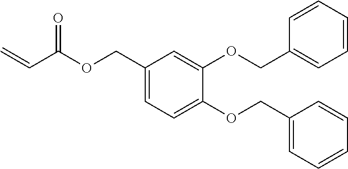 [SMILES: C=CC(=O)OCc1ccc(OCc2ccccc2)c(OCc2ccccc2)c1]

Formula below (a-1-31) (OP=2.67, boiling point=417.2° C., 80° C. vapor pressure <0.0001 mmHg, molecular weight=268.3)

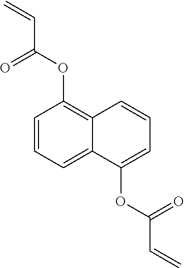 [SMILES: C=CC(=O)Oc1cccc2c(OC(=O)C=C)cccc12]

Formula below (a-1-32) (OP=2.67, boiling point=417.2° C., 80° C. vapor pressure <0.0001 mmHg, molecular weight=268.3)

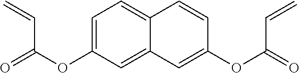 [SMILES: C=CC(=O)Oc1ccc2ccc(OC(=O)C=C)cc2c1]

Formula below (a-1-33) (OP=2.67, boiling point=417.2° C., 80° C. vapor pressure <0.0001 mmHg, molecular weight=268.3)

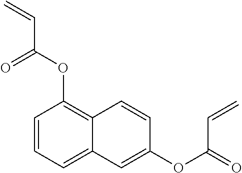 [SMILES: C=CC(=O)Oc1ccc2c(OC(=O)C=C)cccc2c1]

Formula below (a-1-34) (OP=2.67, boiling point=417.2° C., 80° C. vapor pressure <0.0001 mmHg, molecular weight=268.3)

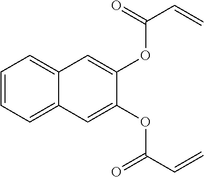 [SMILES: C=CC(=O)Oc1cc2ccccc2cc1OC(=O)C=C]

Formula below (a-1-35) (OP=2.71, boiling point=438.8° C., 80° C. vapor pressure <0.0001 mmHg, molecular weight=296.3)

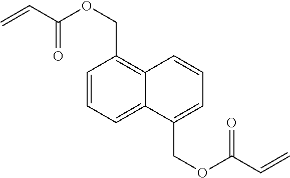 [SMILES: C=CC(=O)OCc1cccc2c(COC(=O)C=C)cccc12]

The polymerizable compound (a) according to the present invention may contain a polymerizable compound (a-2) containing at least Si atoms. Furthermore, if the polymerizable compound (a) contains the polymerizable compound (a-2), the nonvolatile composition (A′) from which the solvent (d) is removed preferably contains Si atoms of 10 wt % or more with respect to the whole nonvolatile composition (A′).

As an example of the polymerizable compound (a-2) containing at least Si atoms, it may have a linear structure or a branched structure. For example, as cyclic siloxane compounds, the following structures can be used. An example of a polymerizable functional group in a group Q having a polymerizable functional group is a radical polymerizable functional group. Practical examples of the radical polymerizable functional group are a (meth)acrylic group, a (meth)acrylamide group, a vinylbenzene group, an allyl ether group, a vinylether group, and a maleimide group. The group Q having a polymerizable functional group need only be a group having the above-described polymerizable functional group.

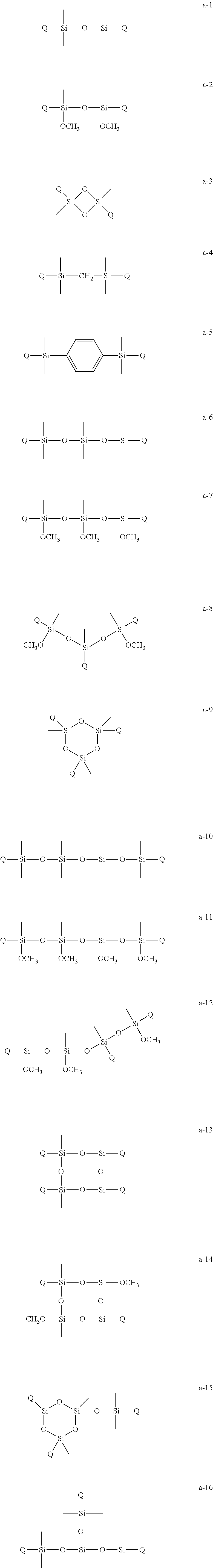

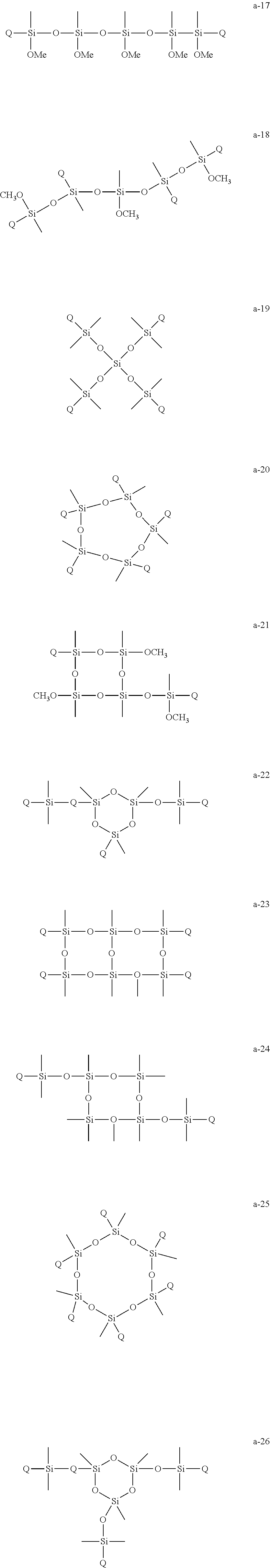

Other examples of the polymerizable compound (a-2) are a silsesquioxane skeleton as indicated by chemical formula (I) below and a silicone skeleton as indicated by chemical formula (II). In chemical formula (I), m+n=8 (8≥m≥1), and R₁ is a bivalent organic group. Additionally, in chemical formula (II), A, B, R₂, and R₃ are independently an alkyl group, a cycloalkyl group, an alkoxy group, a phenyl group, and hydroxyl group whose carbon number is 1 to 6, t is an integer of 1 to 3, and at least one of A and B is a polymerizable functional group.

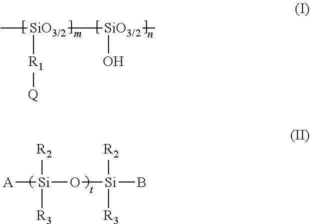

An example of a polymerizable functional group in groups Q, A, and B having a polymerizable functional group is a radical polymerizable functional group. The radical polymerizable functional group may have a linear structure or a branched structure. Detailed examples of the radical polymerizable functional group are a (meth)acrylate-based compound, a (meth)acrylamide-based compound, a vinylbenzene-based compound, an aryl ether-based compound, a vinyl ether-based compound, and a maleimide-based compound. The group Q having a polymerizable functional group can be a group having the above-described polymerizable functional group.

A silicon-containing (meth)acrylate-based compound is a compound having one or more acryloyl groups or methacryloyl groups. Examples of a silicon-containing monofunctional (meth)acrylate-based compound having one acryloyl group or methacryloyl group are as follows, but the compound is not limited to these examples.
(2-acryloylethoxy)trimethylsilane,
N-(3-acryloyl-2-hydroxypropyl)-3-aminopropyltriethoxysilane, acryloxymethyltrimethoxysilane,
(acryloxymethyl)phenethyltrimethoxysilane,
acryloxymethyltrimethylsilane,
(3-acryloxypropyl)dimethylmethoxysilane,
(3-acryloxypropyl)methylbis(trimethylsiloxy)silane,
(3-acryloxypropyl)methyldichlorosilane,
(3-acryloxypropyl)methyldiethoxysilane,
(3-acryloxypropyl)methyldimethoxysilane,
(3-acryloxypropyl)trichlorosilane,
(3-acryloxypropyl)trimethoxysilane,
(3-acryloxypropyl)tris(trimethylsiloxy)silane,
acryloxytriisopropylsilane,
acryloxytrimethylsilane,
methacryloxymethyltrimethoxysilane,
O-(methacryloxyethoxy)carbamoylpropylmethyldimethoxysilane,
(methacryloxymethyl)bis(trimethylsiloxy)methylsilane,
N-(3-methacryloyl-2-hydroxypropyl)-3-aminopropyltriethoxysilane,
(methacryloxymethyl)methyldimethoxysilane,
(methacryloxymethyl)methyldiethoxysilane,
methacryloxymethyltriethoxysilane,
methacryloxypropyltrimethoxysilane,
methacryloylpropyltriisopropoxysilane,
O-(methacryloxyethyl)-N-(triethoxysilylpropyl) carbamate,
methacryloxypropylmethyldimethoxysilane,
methacryloxypropylmethyldiethoxysilane,
methacryloxypropyldimethylmethoxysilane,
methacryloxypropyldimethylethoxysilane,
(methacryloxymethyl)dimethylethoxysilane,
methacryloxypropyltriethoxysilane,
methacryloxypropylsilatrane,
methacryloxypentamethyldisiloxane,
(methacryloxymethyl)phenyldimethylsilane,
methacryloxytrimethylsilane,
methacryloxymethyltrimethylsilane,
(3-methacryloxy-2-hydroxypropoxypropyl)methyl bis(trimethylsiloxy)silane,
methacryloxypropylpentamethyldisiloxane,
O-(methacryloxyethyl)-3-[bis(trimethylsiloxy)methylsilyl]propylcarbamate,
methacryloxymethyltris(trimethylsiloxy)silane,
methacryloxyethoxytrimethylsilane,
(3-methacryloxy-2-hydroxypropoxypropyl)methyl bis(trimethylsiloxy)silane,
methacryloxypropyltris(vinyldimethylsiloxy)silane,
methacryloxypropyltris(trimethylsiloxy)silane,
3-methacryloxypropyltriacetoxysilane,
methacryloxypropylmethyldichlorosilane,
methacryloxypropyltrichlorosilane,
3-methacryloxypropylbis(trimethylsiloxy)methylsilane,
3-methacryloxypropyldimethylchlorosilane,
O-methacryloxy(polyethyleneoxy)trimethylsilane,
poly(methacryloxypropylsilsesquioxane),
methacryloxypropylheptaisobutyl-T8-silsesquioxane, and
methacryloxypropyltris(trimethylsiloxy)silane

Examples of the commercially available products of the above-described silicon-containing monofunctional (meth)acrylic compounds are as follows, but the products are not limited to these examples.

SIA0160.0, SIA0180.0, SIA0182.0, SIA0184.0, SIA0186.0, SIA0190.0, SIA0194.0, SIA0196.0, SIA0197.0, SIA0198.0, SIA0199.0, SIA0200.0, SIA0200.A1, SIA0210.0, SIA0315.0, SIA0320.0, SIM6483.0, SIM6487.5, SIM6480.76, SIM6481.2, SIM6486.1, SIM6481.1, SIM6481.46, SIM6481.43, SIM6482.0, SIM6487.4, SIM6487.35, SIM6480.8, SIM6486.9, SIM6486.8, SIM6486.5, SIM6486.4, SIM6481.3, SIM6487.3, SIM6487.1, SIM6487.6, SIM6486.14, SIM6481.48, SIM6481.5, SIM6491.0, SIM6485.6, SIM6481.15, SIM6487.0, SIM6481.05, SIM6485.8, SIM6481.0, SIM6487.4LI, SIM6481.16, SIM6487.8, SIM6487.6HP, SIM6487.17, SIM6486.7, SIM6487.2, SIM6486.0, SIM6486.2, SIM6487.6-06, SIM6487.6-20, SIM6485.9, SST-R8C42, SLT-3R01, and SIM6486.65 (manufactured by GELEST), and TM-0701T, FM-0711, FM-0721, and FM-0725 (manufactured by JNC)

A silicon-containing (meth)acrylamide-based compound is a compound having one or more acrylamide groups or methacrylamide groups. Examples of a silicon-containing monofunctional (meth)acrylamide-based compound having one acrylamide group or methacrylamide group are as follows, but the compound is not limited to these examples.
3-acrylamidopropyltrimethoxysilane, and 3-acrylamidopropyltris(trimethylsiloxy)silane

Examples of the commercially available products of the above-described silicon-containing monofunctional (meth)acrylamide compounds are as follows, but the products are not limited to these examples.
SIA0146.0, and SIA0150.0 (manufactured by GELEST)

Examples of a polyfunctional (meth)acrylate-based compound having two or more acryloyl groups or methacryloyl groups are as follows, but the compound is not limited to these examples.
linear polydimethylsiloxane modified on both ends with acryloxypropyl groups, linear polydimethylsiloxane modified on both ends with methacryloxypropyl groups,
cyclic siloxane modified with multiple acryloxypropyl groups,
cyclic siloxane modified with multiple methacryloxypropyl groups,
silsesquioxane modified with multiple acryloxypropyl groups, and
silsesquioxane modified with multiple methacryloxypropyl groups

Examples of the commercially available products of the above-described silicon-containing polyfunctional (meth)acrylate compounds are as follows, but the products are not limited to these examples.

SIA0200.2, SIA0200.3, SIM6487.42, DMS-R11, DMS-R05, DMS-R22, DMS-R18, DMS-R31 (manufactured by GELEST), FM-7711, FM-7721, FM-7725 (manufactured by JNC), X-22-2445 (manufactured by Shin-Etsu Chemical), and AC-SQ TA-100, MAC-SQ TM-100, AC-SQ SI-20, MAC-SQ SI-20 (manufactured by TOAGOSEI)

Also, for example, according to known literature 1, the following can be synthesized and/or obtained.
linear modified polydimethylsiloxane with methacryloxypropyl groups on both ends (MA-Si-12), 8-membered ring siloxane modified with four methacryloxypropyl groups (8-ring), and 10-membered ring siloxane modified with five methacryloxypropyl groups (10-ring).

Known literature 1: “Ultraviolet curable branched siloxanes as low-k dielectricsforimprint lithography” by Ogawa et al.

The polymerizable compound (a) according to the present invention may include a polymerizable compound (a-3) containing at least F atoms. A fluorine compound as the polymerizable compound (a-3) may be understood as a fluorine-containing polymerizable compound. In this specification, the fluorine-containing polymerizable compound is a compound that reacts with a polymerizing factor (for example, a radical) generated from the photopolymerization initiator (b), and forms a film made of a polymer compound by a chain reaction (polymerization reaction).

An example of the fluorine-containing polymerizable compound is a radical polymerizable compound. The polymerizable compound (a-3) can be formed by only one type of a polymerizable compound, and can also be formed by a plurality of types (one or more types) of polymerizable compounds.

Examples of the fluorine-containing radical polymerizable compound are a (meth)acrylate-based compound, a (meth)acrylamide-based compound, a vinylbenzene-based compound, an aryl ether-based compound, a vinyl ether-based compound, and a maleimide-based compound.

Examples of the commercially available products of the above-described fluorine-containing monofunctional (meth)acrylate-based compounds are as follows, but the products are not limited to these examples.
2,2,2-trifluoroethyl acrylate, 2,2,3,4,4,4-hexafluorobutyl methacrylate, 1,1,1,3,3,3-hexafluoroisopropyl acrylate, 2,2,3,3,4,4,4-hexafluoroisopropyl methacrylate 2,4,4,4-heptafluorobutyl methacrylate, 2,2,2-trifluoroethyl methacrylate, 1,1,1,3,3,3-hexafluoroisopropyl methacrylate, 1H,1H,2H,2H-nonafluorohexyl
methacrylate, 1H,1H,2H,2H-nonafluorohexyl acrylate, 1H,1H,2H,2H-nonafluorohexyl methacrylate, 1H,1H,5H-octafluoropentyl acrylate,
pentafluorophenyl acrylate, 2,2,3,3,3-pentafluoropropyl methacrylate,
pentafluorobenzyl methacrylate, 2,2,3,3-tetrafluoropropyl acrylate, 1H,1H,2H,2H-tridecafluoro-n-octyl methacrylate, 1H,1H,2H,2H-tridecafluoro-n-octyl acrylate,
2,2,3,3-tetrafluoropropyl methacrylate, 1H,1H,2H,2H-heptadecafluorodecyl acrylate, 2,2,3,3,4,4,5,5,6,6,7,7-dodecafluoroheptyl acrylate,
2,2,3,3,4,4,5,5,6,6,7,7-dodecafluoroheptyl methacrylate, 1H,1H,5H-octafluoropentyl acrylate, meth Pentafluorophenyl acrylate (manufactured by Tokyo Chemical Industry)
C6(meth)acrylate, C4(meth)acrylate, C2(meth)acrylate (manufactured by Uni-chem) Viscoat 3F, Viscoat 4F, Viscoat 8F, Viscoat 8FM, Viscoat 13F (manufactured by OSAKA ORGANIC CHEMICAL INDUSTRY)
1H,1H,2H,2H-heptadecafluorodecyl methacrylate, 1,1,1,3,3,3-hexafluoroisopropyl methacrylate, 1H,1H,5H-octafluoropentyl methacrylate, pentafluorophenyl acrylate, 2,2,2-trifluoroethyl acrylate, 2,2,2-trifluoroethyl methacrylate (manufactured by Polysciences)
methyl-2-fluoroacrylate, 2,2,2-trifluoroethyl acrylate, 2,2,3,3,3-pentafluoropropyl acrylate, 2-(perfluorobutyl)ethyl acrylate, 3-perfluorohexyl-2-hydroxypropyl acrylate, 1H,1H,3H-tetrafluoropropyl acrylate, 1H,1H,5H-octafluoropentyl acrylate, 1H,1H,7H-dodecafluoroheptyl acrylate, 1H-1-(trifluoromethyl)trifluoroethyl acrylate, 1H,1H,3H-hexafluorobutyl acrylate,
2,2,2-trifluoroethyl methacrylate, 2,2,3,3,3-pentafluoropropyl methacrylate, 2-(perfluorobutyl)ethyl methacrylate, 1H,1H,3H-tetrafluoropropyl methacrylate,
1H,1H,5H-octafluoropentyl methacrylate, 1H,1H,7H-dodecafluoroheptyl methacrylate, 1H-1-(trifluoromethyl)trifluoroethyl methacrylate, 1H,1H,3H-hexafluorobutyl methacrylate (manufactured by DAIKIN)

Examples of the above-described fluorine-containing polyfunctional (meth)acrylate-based compound obtained using a method disclosed in Japanese Patent No. 3963028 are as follows, but the compound is not limited to these examples.

A compound obtained by introducing a linking group to the polyalcohol part of trivalent trimethylolethane, quadrivalent pentaerythritol, or hexavalent dipentaerythritol using a normal organic synthetic reaction, forming a core part containing fluorine in high content by a whole fluorination reaction, and then introducing an acrylic group to an end.

The above-described fluorine-containing polyfunctional (meth)acrylate-based compound may be a commercially available product.

Also, a commercially available product may be used as the curable composition (A), and examples are PAK-TRAD manufactured by TOYO GOSEI and UT-UCa-368 manufactured by AGC Seimi Chemical.

The blending ratio of the polymerizable compound (a) in the nonvolatile composition (A′) is preferably 40 wt % or more and 99 wt % or less, more preferably 50 wt % or more and 95 wt % or less, and further preferably 60 wt % or more and 90 wt % or less. When the blending ratio of the polymerizable compound (a) is 40 wt % or more, the mechanical strength of the cured film of the curable composition (A) increases. Also, when the blending ratio of the polymerizable compound (a) is 99 wt % or less, it is possible to increase the blending ratios of the photopolymerization initiator (b) or the nonpolymerizable compound (c), and obtain characteristics such as a high photopolymerization rate. At least a part of the polymerizable compound (a) including one or more types of polymerizable compounds can be polymers having a polymerizable functional group. A polymer like this preferably contains at least a cyclic structure such as an aromatic structure, an aromatic heterocyclic structure, or an alicyclic structure. For example, the polymer preferably contains at least one of constituent units represented by structures (1) to (6) below:

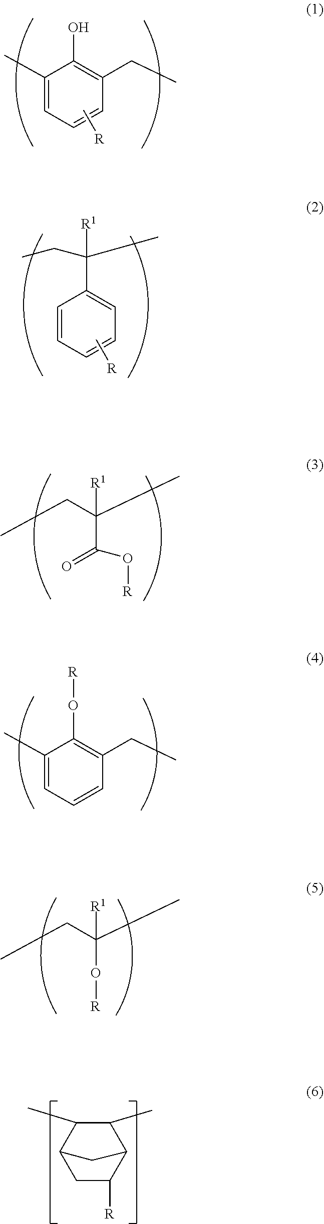

In the structures (1) to (6), a substituent group R is a substituent group containing partial structures each independently containing an aromatic ring, and R¹ is a hydrogen atom or a methyl group. In this specification, in constituent units represented by the structures (1) to (6), a portion other than R is the main chain of a specific polymer. The formula weight of the substituent group R is 80 or more, preferably 100 or more, more preferably 130 or more, and further preferably 150 or more. The upper limit of the formula weight of the substituent group R is practically 500 or less.

A polymer having a polymerizable functional group is normally a compound having a weight-average molecular weight of 500 or more. The weight-average molecular weight is preferably 1,000 or more, and more preferably 2,000 or more. The upper limit of the weight-average molecular weight is not particularly determined, but is preferably, for example, 50,000 or less. When the weight-average molecular weight is set at the above-described lower limit or more, it is possible to set the boiling point at 250° C. or more, and further improve the mechanical properties after curing. Also, when the weight-average molecular weight is set at the above-described upper limit or less, the solubility to the solvent increases, and the flowability of discretely arranged droplets is maintained because the viscosity is not too high. This makes it possible to further improve the flatness of the liquid film surface. Note that the weight-average molecular weight (Mw) in the present invention is a molecular weight measured by gel permeation chromatography (GPC) unless it is specifically stated otherwise.

Practical examples of the polymerizable functional group of the polymer are a (meth)acryloyl group, an epoxy group, an oxetane group, a methylol group, a methylol ether group, and a vinyl ether group. A (meth)acryloyl group is particularly favorable from the viewpoint of polymerization easiness.

When adding the polymer having the polymerizable functional group as at least a part of the polymerizable compound (a), the blending ratio can freely be set as long as the blending ratio falls within the range of the viscosity regulation to be described later. For example, the blending ratio to the total mass of all the components except for the solvent (d1) is preferably 0.1 wt % or more and 60 wt % or less, more preferably 1 wt % or more and 50 wt % or less, and further preferably 10 wt % or more and 40 wt % or less. When the blending ratio of the polymer having the polymerizable functional group is set at 0.1 wt % or more, it is possible to improve the heat resistance, the dry etching resistance, the mechanical strength, and the low volatility. Also, when the blending ratio of the polymer having the polymerizable functional group is set at 60 wt % or less, it is possible to make the blending ratio fall within the range of the upper limit regulation of the viscosity (to be described later).

In this specification, the photopolymerization initiator (b) is a compound that senses light having a predetermined wavelength and generates a polymerization factor (radical) described earlier. More specifically, the photopolymerization initiator is a polymerization initiator (radical generator) that generates a radical by light (infrared light, visible light, ultraviolet light, far-ultraviolet light, X-ray, a charged particle beam such as an electron beam, or radiation). The photopolymerization initiator (b) can be formed by only one type of a photopolymerization initiator, and can also be formed by a plurality of types of photopolymerization initiators.

Examples of the radical generator are as follows, but the radical generator is not limited to these examples.
2,4,5-triarylimidazole dimers that can have substituent groups, such as a 2-(o-chlorophenyl)-4,5-diphenylimidazole dimer, a 2-(o-chlorophenyl)-4,5-di(methoxyphenyl)imidazole dimer, a 2-(o-fluorophenyl)-4,5-diphenylimidazole dimer, and a 2-(o- or p-methoxyphenyl)-4,5-diphenylimidazole dimer;
benzophenone derivatives such as benzophenone, N,N′-tetramethyl-4,4′-diaminobenzophenone (Michiler's ketone), N,N′-tetraethyl-4,4′-diaminobenzophenone, 4-methoxy-4′-dimethylaminobenzophenone, 4-chlorobenzophenone, 4,4′-dimethoxybenzophenone, and 4,4′-diaminobenzophenone; α-amino aromatic ketone derivatives such as 2-benzyl-2-dimethylamino-1-(4-morpholinophenyl)-butanone-1,2-methyl-1-[4-(methylthio)phenyl]-2-morpholino-propane-1-one; quinones such as 2-ethylanthraquinone, phenanthrenequinone, 2-t-butylanthraquinone,
octamethylanthraquinone, 1,2-benzanthraquinone, 2,3-benzanthraquinone, 2-phenylanthraquinone, 2,3-diphenylamthraquinone, 1-chloroanthraquinone, 2-methylanthraquinone, 1,4-naphtoquinone, 9,10-phenanthraquinone, 2-methyl-1,4-naphtoquinone, and 2,3-dimethylanthraquinone; benzoin ether derivatives such as benzoin methyl ether, benzoin ethyl ether, and benzoin phenyl ether; benzoin derivatives such as benzoin, methyl benzoin, ethyl benzoin, and propyl benzoin;
benzyl derivatives such as benzyldimethylketal; acridine derivatives such as 9-phenylacridine and 1,7-bis(9,9′-acrydinyl)heptane; N-phenylglycine derivatives such as N-phenylglycine; acetophenone derivatives such as acetophenone, 3-methylacetophenone, acetophenone benzylketal, 1-hydroxycylohexyl phenylketone, and 2,2-dimethoxy-2-phenyl acetophenone; thioxanthone derivatives such as thioxanthone, diethylthioxanthone, 2-isopropylthioxanthone,
and 2-chlorothioxanthone; acylphosphine oxide derivatives such as 2,4,6-trimethylbenzoyldiphenylphosphine oxide, bis(2,4,6-trimethylbenzoyl)phenylphosphine oxide, and bis-(2,6-dimethoxybenzoyl)-2,4,4-trimethylpentylphosphine oxide; oxime ester derivatives such as 1,2-octanedione, 1-[4-(phenylthiol)-,2-(O-benzoyloxime)], ethanone, 1-[9-ethyl-6-(2-methylbenzoyl)-9H-carbazole-3-yl]-, and 1-(O-acetyloxime); and xanthone,
fluorenone, benzaldehyde, fluorene, anthraquinone, triphenylamine, carbazole, 1-(4-isopropylphenyl)-2-hydroxy-2-methylprapane-1-one, and 2-hydroxy-2-methyl-1-phenylpropane-1-one.

Examples of commercially available products of the above-described radical generators are as follows, but the products are not limited to these examples.

Irgacure 184, 369, 651, 500, 819, 907, 784, and 2959, CGI-1700, -1750, and -1850, CG24-61, Darocur 1116 and 1173, Lucirin® TPO, LR8893, and LR8970 (manufactured by BASF), and Ubecryl P36 (manufactured by UCB).

Of the above-described radical generators, the photopolymerization initiator (b) is preferably an acylphosphine oxide-based polymerization initiator. Note that of the above-described radical generators, the acylphosphine oxide-based polymerization initiators are as follows.

Acylphosphine oxide compounds such as 2,4,6-trimethylbenzoyl diphenylphosphine oxide, bis(2,4,6-trimethylbenzoyl)phenylphosphine oxide, and bis(2,6-dimethoxybenzoyl)-2,4,4-trimethylpentylphosphine oxide.

The blending ratio of the photopolymerization initiator (b) in the nonvolatile composition (A′) is preferably 0.1 wt % or more and 50 wt % or less, more preferably 0.1 wt % or more and 20 wt % or less, and further preferably 1 wt % or more and 20 wt % or less. When the blending ratio of the photopolymerization initiator (b) is set at 0.1 wt % or more, the curing rate of the composition increases, so the reaction efficiency can be improved. Also, when the blending ratio of the photopolymerization initiator (b) is set at 50 wt % or less, a cured film having mechanical strength to some extent can be obtained.

In addition to the polymerizable compound (a) and the photopolymerization initiator (b), the curable composition (A) of the present invention can further contain a nonpolymerizable compound (c) within a range that does not impair the effect of the present invention in accordance with various purposes. An example of the nonpolymerizable compound (c) is a compound that does not contain a polymerizable functional group such as a (meth)acryloyl group, and does not have the ability to sense light having a predetermined wavelength and generate the polymerization factor (radical) described previously. Examples of the nonpolymerizable compound (c) are a sensitizer, a hydrogen donor, a surfactant (c-1), an antioxidant, a polymer component, and other additives. As the nonpolymerizable compound (c), a plurality of types of the above-described compounds may be contained.

The sensitizer is a compound that is properly added for the purpose of promoting the polymerization reaction and improving the reaction conversion rate. As the sensitizer, it is possible to use one type of a compound alone, or to use two or more types of compounds by mixing them.

An example of the sensitizer is a sensitizing dye. The sensitizing dye is a compound that is excited by absorbing light having a specific wavelength and has an interaction with the photopolymerization initiator (b). The “interaction” herein mentioned is energy transfer or electron transfer from the sensitizing dye in the excited state to the photopolymerization initiator that is the photopolymerization initiator (b). Practical examples of the sensitizing dye are as follows, but the sensitizing dye is not limited to these examples.

An anthracene derivative, an anthraquinone derivative, a pyrene derivative, a perylene derivative, a carbazole derivative, a benzophenone derivative, a thioxanthone derivative, a xanthone derivative, a coumarin derivative, a phenothiazine derivative, a camphorquinone derivative, an acridinic dye, a thiopyrylium salt-based dye, a merocyanine-based dye, a quinoline-based dye, a styryl quinoline-based dye, a ketocoumarin-based dye, a thioxanthene-based dye, a xanthene-based dye, an oxonol-based dye, a cyanine-based dye, a rhodamine-based dye, and a pyrylium salt-based dye.

The hydrogen donor is a compound that reacts with an initiation radical generated from the photopolymerization initiator that is the photopolymerization initiator (b) or a radical at a polymerization growth end, and generates a radical having higher reactivity. The hydrogen donor is preferably added when the photopolymerization initiator that is the photopolymerization initiator (b) is a photo-radical generator.

Practical examples of the hydrogen donor as described above are as follows, but the hydrogen donor is not limited to these examples.

Amine compounds such as n-butylamine, di-n-butylamine, tri-n-butylphosphine, allylthiourea, s-benzylisothiuronium-p-toluenesulfinate, triethylamine, diethylaminoethyl methacrylate, triethylenetetramine, 4,4′-bis(dialkylamino)benzophenone, N,N-dimethylamino ethylester benzoate, N,N-dimethylamino isoamylester benzoate, pentyl-4-dimethylamino benzoate, triethanolamine, and N-phenylglycine; and mercapto compounds such as 2-mercapto-N-phenylbenzoimidazole and mercapto propionate ester.

It is possible to use one type of a hydrogen donor alone, or to use two or more types of hydrogen donors by mixing them. The hydrogen donor can also have a function as a sensitizer.

In the present invention, a surfactant (c-1) is added to the curable composition (A) in order to suppress extrusion and oozing of the curable composition. The surfactant (c-1) also functions as an internal mold release agent that reduces the interface bonding force between a mold and the curable composition, that is, reduces the mold release force in a mold release step (to be described later). In this specification, “internal” means that the mold release agent is added to the curable composition in advance before a curable composition arranging step. As the surfactant (c-1), it is possible to use surfactants such as a silicone-based surfactant, a fluorine-based surfactant, and a hydrocarbon-based surfactant. Note that the surfactant (c-1) according to the present invention is not polymerizable. It is possible to use one type of surfactant (c-1) alone, or to use two or more types of surfactants (c-1) by mixing them.

The fluorine-based surfactant includes the following.

A polyalkylene oxide (for example, polyethylene oxide or polypropylene oxide) adduct of alcohol having a perfluoroalkyl group, and a polyalkylene oxide (for example, polyethylene oxide or polypropylene oxide) adduct of perfluoropolyether.

Note that the fluorine-based surfactant can have a hydroxyl group, an alkoxy group, an alkyl group, an amino group, or a thiol group in a portion (for example, a terminal group) of the molecular structure. An example is pentadecaethyleneglycol mono1H,1H,2H,2H-perfluorooctylether.

It is also possible to use a commercially available product as the fluorine-based surfactant. Examples of the commercially available product of the fluorine-based surfactant are as follows.

MEGAFACE® F-444, TF-2066, TF-2067, and TF-2068, and DEO-15 (abbreviation) (manufactured by DIC);
Fluorad FC-430 and FC-431 (manufactured by Sumitomo 3M) Surflon® S-382 (manufactured by AGC)
EFTOP EF-122A, 122B, 122C, EF-121, EF-126, EF-127, and MF-100 (manufactured by Tochem Products)
PF-636, PF-6320, PF-656, and PF-6520 (manufactured by OMNOVA Solutions) UNIDYNE® DS-401, DS-403, and DS-451 (manufactured by DAIKIN) FUTAGENT® 250, 251, 222F, and 208G (manufactured by NEOS)

The surfactant (c-1) can also be a hydrocarbon-based surfactant. The hydrocarbon-based surfactant includes an alkyl alcohol polyalkylene oxide adduct obtained by adding alkylene oxide having a carbon number of 2 to 4 to alkyl alcohol having a carbon number of 1 to 50, and polyalkylene oxide.

Examples of the alkyl alcohol polyalkylene oxide adduct are as follows.

A methyl alcohol ethylene oxide adduct, a decyl alcohol ethylene oxide adduct, a lauryl alcohol ethylene oxide adduct, a cetyl alcohol ethylene oxide adduct, a stearyl alcohol ethylene oxide adduct, and a stearyl alcohol ethylene oxide/propylene oxide adduct.

Note that the terminal group of the alkyl alcohol polyalkylene oxide adduct is not limited to a hydroxyl group that can be manufactured by simply adding polyalkylene oxide to alkyl alcohol. This hydroxyl group can also be substituted by a polar functional group such as a carboxyl group, an amino group, a pyridyl group, a thiol group, or a silanol group, or by a hydrophobic group such as an alkyl group or an alkoxy group.

Examples of polyalkylene oxide are as follows.

Polyethylene glycol, polypropylene glycol, their mono or dimethyl ether, mono or dioctyl ether, mono or dinonyl ether, and mono or didecyl ether, monoadipate ester, monooleate ester, monostearate ester, and monosuccinate ester.

A commercially available product can also be used as the alkyl alcohol polyalkylene oxide adduct. Examples of the commercially available product of the alkyl alcohol polyalkylene oxide adduct are as follows.

Polyoxyethylene methyl ether (a methyl alcohol ethylene oxide adduct) (BLAUNON MP-400, MP-550, and MP-1000) manufactured by AOKI OIL INDUSTRIAL, polyoxyethylene decyl ether (a decyl alcohol ethylene oxide adduct) (FINESURF D-1303, D-1305, D-1307, and D-1310) manufactured by AOKI OIL INDUSTRIAL, polyoxyethylene lauryl ether (a lauryl alcohol ethylene oxide adduct) (BLAUNON EL-1505) manufactured by AOKI OIL INDUSTRIAL, polyoxyethylene cetyl ether (a cetyl alcohol ethylene oxide adduct) (BLAUNON CH-305 and CH-310) manufactured by AOKI OIL INDUSTRIAL, polyoxyethylene stearyl ether (a stearyl alcohol ethylene oxide adduct) (BLAUNON SR-705, SR-707, SR-715, SR-720, SR-730, and SR-750) manufactured by AOKI OIL INDUSTRIAL, randomly polymerized polyoxyethylene polyoxypropylene stearyl ether (BLAUNON SA-50/50 1000R and SA-30/70 2000R) manufactured by AOKI OIL INDUSTRIAL, polyoxyethylene methyl ether (Pluriol® A760E) manufactured by BASF, and polyoxyethylene alkyl ether (EMULGEN series) manufactured by KAO.

A commercially available product can also be used as polyalkylene oxide. An example is an ethylene oxide/propylene oxide copolymer (Pluronic PE6400) manufactured by BASF.

Also, the surfactant (c-1) may be a silicone-based surfactant. Examples of a silicone-based surfactant are as follows. For example, product name SI-10 series (manufactured by TAKEMOTO OIL & FAT), MEGAFACE Paintad 31 (manufactured by DIC), and KP-341 (manufactured by Shin-Etsu Chemical) can be used.

The surfactant (c-1) may be a surfactant containing at least both fluorine atoms and silicone atoms. Examples of the surfactant containing both fluorine atoms and silicone atoms are as follows.

Product names X-70-090, X-70-091, X-70-092, X-70-093 (manufactured by Shin-Etsu Chemical), and product names MEGAFACE R-08 and XRB-4 (manufactured by DIC)

The blending ratio of the nonpolymerizable compound (c) in the nonvolatile composition (A′) except for the surfactant is preferably 0.01 wt % or more and 50 wt % or less. The blending ratio of the nonpolymerizable compound (c) in the nonvolatile composition (A′) except for the surfactant is more preferably 0.01 wt % or more and 50 wt % or less, and further preferably 0.01 wt % or more and 20 wt % or less. When the blending ratio of the nonpolymerizable compound (c) except for the surfactant is set at 50 wt % or less, a cured film having mechanical strength to some extent can be obtained.

The curable composition (A) of the present invention contains a solvent having a boiling point of 100° C. or more and less than 250° C. at normal pressure as the solvent (d). The solvent (d) is a solvent that dissolves the polymerizable compound (a), the photopolymerization initiator (b), and the nonpolymerizable compound (c), and examples are an alcohol-based solvent, a ketone-based solvent, an ether-based solvent, an ester-based solvent, and a nitrogen-containing solvent. As the solvent (d), it is possible to use one type of a solvent alone, or to use two or more types of solvents by combining them. The boiling point at normal pressure of the solvent (d) is 100° C. or more, preferably 140° C. or more, and particularly preferably 150° C. or more. The boiling point at normal pressure of the solvent (d) is less than 250° C., and preferably less than 200° C. If the boiling point of the solvent (d) at normal pressure is less than 100° C., the volatilization speed in the waiting step to be described later is too high. For this reason, the solvent (d) may volatilize before the droplets of the curable composition (A) bond to each other, and the droplets of the curable composition (A) may not bond to each other. Also, if the boiling point at normal pressure of the solvent (d) is 250° C. or more, it is possible that the volatilization of the solvent (d) is insufficient in the waiting step to be described later, so the solvent (d) remains in the nonvolatile composition (A′). Here, if the solvent (d) includes one or more types of solvents, the boiling point of each of the one or more types of solvents at normal pressure is preferably 100° C. or more and less than 250° C. (for example, 100° C. or more and less than 200° C.).

Examples of the alcohol-based solvent are as follows.

Monoalcohol-based solvents such as methanol, ethanol, n-propanol, iso-propanol, n-butanol, iso-butanol, sec-butanol, tert-butanol, n-pentanol, iso-pentanol, 2-methylbutanol, sec-pentanol, tert-pentanol, 3-methoxybutanol, n-hexanol, 2-methylpentanol, sec-hexanol, 2-ethylbutanol, sec-heptanol, 3-heptanol, n-octanol, 2-ethylhexanol, sec-octanol, n-nonyl alcohol, 2,6-dimethylheptanol-4, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; and polyalcohol-based solvents such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, and glycerin.

Examples of the ketone-based solvent are as follows.

Acetone, methylethylketone, methyl-n-propylketone, methyl-n-butylketone, diethylketone, methyl-iso-butylketone, methyl-n-pentylketone, ethyl-n-butylketone, methyl-n-hexylketone, di-iso-butylketone, trimethylnonanon, cyclohexanone, methylcyclohexanone, 2,4-pentanedione, acetonylacetone, diacetone alcohol, acetophenone, and fenthion.

Examples of the ether-based solvent are as follows.

Ethyl ether, iso-propyl ether, n-butyl ether, n-hexyl ether, 2-ethylhexyl ether, ethylene oxide, 1,2-propylene oxide, dioxolane, 4-methyldioxolane, dioxane, dimethyldioxane, 2-methoxyethanol, 2-ethoxyethanol, ethylene glycol diethyl ether, 2-n-butoxyethanol, 2-n-hexoxyethanol, 2-phenoxyethanol, 2-(2-ethylbutoxy)ethanol, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxy triglycol, tetraethylene glycol di-n-butyl ether, 1-n-butoxy-2-propanol, 1-phenoxy-2-propanol, propylene glycol monomethyl ether, propylene glycol monoethyl ether, propylene glycol monopropyl ether, dipropylene glycol monomethyl ether, dipropylene glycol monoethyl ether, dipropylene glycol monopropyl ether, tripropylene glycol monomethyl ether, tetrahydrofuran, and 2-methyltetrahydrofuran.

Examples of the ester-based solvent are as follows.

Diethyl carbonate, methyl acetate, ethyl acetate, amyl acetate, γ-butyrolactone, γ-valerolactone, n-propyl acetate, iso-propyl acetate, n-butyl acetate, iso-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxy triglycol acetate, ethyl propionate, n-butyl propionate, iso-amyl propionate, diethyl oxalate, di-n-butyl oxalate, methyl lactate, ethyl lactate, n-butyl lactate, n-amyl lactate, diethyl malonate, dimethyl phthalate, and diethyl phthalate.

Examples of the nitrogen-containing solvent are as follows.

N-methylformamide, N,N-dimethylformamide, N,N-diethylformamide, acetamide, N-methylacetamide, N,N-dimethylacetamide, N-methylpropionamide, and N-methylpyrrolidone.

Of the above-described solvents, the ether-based solvent and the ester-based solvent are favorable. Note that an ether-based solvent and an ester-based solvent each having a glycol structure are more favorable from the viewpoint of good film formation properties.

Further favorable examples of the solvent are as follows.

Propylene glycol monomethyl ether, propylene glycol monoethyl ether, propylene glycol monopropyl ether, propylene glycol monomethyl ether acetate, propylene glycol monoethyl ether acetate, and propylene glycol monopropyl ether acetate.

A particularly favorable example is propylene glycol monomethyl ether acetate. Note that (ethyl)isocyanurate di(meth)acrylate is also favorable.

In the present invention, a favorable solvent is a solvent having at least one of an ester structure, a ketone structure, a hydroxyl group, and an ether structure. More specifically, a favorable solvent is one solvent or a solvent mixture selected from propylene glycol monomethyl ether acetate (boiling point=146° C.), propylene glycol monomethyl ether, cyclohexanone, 2-haptanone, γ-butyrolactone, and ethyl lactate.

In the present invention, a polymerizable compound having a boiling point of 80° C. or more and less than 250° C. at normal pressure is also usable as the solvent (d). Examples of the polymerizable compound having a boiling point of 80° C. or more and less than 250° C. at normal pressure are as follows.

Cyclohexyl acrylate (boiling point=198° C.), benzyl acrylate (boiling point=229° C.), isobornyl acrylate (boiling point=245° C.), tetrahydrofurfuryl acrylate (boiling point=202° C.), trimethylcyclohexyl acrylate (boiling point=232° C.), isooctyl acrylate (217° C.), n-octyl acrylate (boiling point=228° C.), ethoxyethoxyethyl acrylate (boiling point=230° C.), divinylbenzene (boiling point=193° C.), 1,3-diisopropenylbenzene (boiling point=218° C.), styrene (boiling point=145° C.), and α-methylstyrene (boiling point=165° C.).

In the present invention, when the whole of the curable composition (A) is 100 vol %, the content of the solvent (d) can be more than 5 vol % and 95 vol % or less, preferably 15 vol % or more and 85 vol % or less, and further preferably 40 vol % or more and 80 vol % or less. For example, the content of the solvent (d) is 40 vol % or more and 85 vol % or less. If the content of the solvent (d) is smaller than 5 vol %, it is impossible to obtain a thin film after the solvent (d) volatilized under the condition that a practically continuous liquid film can be obtained. On the other hand, if the content of the solvent (d) is larger than 95 vol %, it is impossible to obtain a thick film after the solvent (d) volatilized even when droplets are closely dropped by an inkjet method.

When preparing the curable composition (A) of the present invention, at least the polymerizable compound (a), the photopolymerization initiator (b), and the solvent (d) are mixed and dissolved under a predetermined temperature condition. More specifically, the predetermined temperature condition is 0° C. or more and 100° C. or less. Note that the same applies to a case in which the curable composition (A) contains the solvent (d).

The curable composition (A) of the present invention is a liquid. This is so because droplets of the curable composition (A) are discretely dropped on the high elastic modulus part by an inkjet method in the arranging step to be described later. The viscosity of the curable composition (A) according to the present invention is 2 mPa·s or more and 60 mPa·s or less at 23° C. and at 1 atm, preferably 2 mPa·s or more and 30 mPa·s or less, and more preferably 5 mPa·s or more and 15 mPa·s or less. If the viscosity of the curable composition (A) is smaller than 2 mPa·s, the discharge property of droplets by an inkjet method may be unstable. Also, if the viscosity of the curable composition (A) is larger than 60 mPa·s, it is impossible to form droplets having a volume of about 1.0 to 3.0 pL favorable in the present invention.

The viscosity of the nonvolatile composition (A′) of the present invention is 20 mPa·s or more and 10,000 mPa·s or less at 23° C. and at 1 atm. The viscosity of the nonvolatile composition (A′) may be 30 mPa·s or more and 500 mPa·s or less at 23° C. and at 1 atm, preferably 60 mPa·s or more and 200 mPa·s or less, and further preferably 60 mPa·s or more and 150 mPa·s or less. Note that if the viscosity is lower, for example, less than 20 mPa·s, the flowability of the nonvolatile composition (A′) is high, and when the nonvolatile composition (A′) and the high elastic modulus part 10 are brought into contact with each other, the nonvolatile composition (A′) readily flows from an end portion of the mesa portion 14. Also, if the viscosity is higher than 10,000 mPa·s, the flowability of the nonvolatile composition (A′) is low, and when the nonvolatile composition (A′) and the high elastic modulus part 10 are brought into contact with each other, the speed to reach the edge of the mesa portion 14 of the high elastic modulus part 10 is low. Hence, by using the curable composition (A) in which the viscosity of the nonvolatile composition (A′) is adjusted to 20 mPa·s or more and 10,000 mPa·s or less, imprint processing can be executed at high throughput. It is also possible to suppress defects caused by flowing of the nonvolatile composition (A′) from the mesa portion 14 of the high elastic modulus part 10.

The surface tension of the nonvolatile composition (A′) is preferably 5 mN/m or more and 70 mN/m or less at 23° C. and at 1 atm, more preferably 7 mN/m or more and 50 mN/m or less, and further preferably 10 mN/m or more and 40 mN/m or less. Note that if the surface tension is higher, for example, 5 mN/m or more, a capillary force strongly acts and, therefore, when the nonvolatile composition (A′) and the master mold MM are brought into contact with each other, filling (spread and fill) is completed in a short time. In addition, when the surface tension is 70 mN/m or less, a cured film obtained by curing the curable composition is a cured film having surface smoothness.

The contact angle of the curable composition (A) of the present invention is preferably 0° or more and 900 or less with respect to the surface of the master mold MM. If the contact angle is larger than 90°, droplets on the substrate do not come into contact with each other, and a continuous liquid film cannot be formed.

Also, the contact angle of the curable composition (A) of the present invention is preferably 0° or more and 90° or less with respect to both the surface of the master mold MM and the surface of the high elastic modulus part 10 (replica base material). If the contact angle is larger than 90°, the capillary force acts in a negative direction in the fine pattern FP of the master mold MM or in the gap between the master mold MM and the high elastic modulus part 10 (replica base material). Here, since the negative direction is a direction in which the boundary surface between the master mold MM and the curable composition (A) shrinks, there is possibility that the nonvolatile composition (A′) is not filled in the fine pattern FP of the master mold MM. When the contact angle is small, the capillary force strongly acts and, therefore, the filling speed becomes high.

The curable composition (A) of the present invention preferably contains impurities as little as possible. Note that impurities mean components other than the polymerizable compound (a), the photopolymerization initiator (b), the nonpolymerizable compound (c), and the solvent (d) described above. Therefore, the curable composition (A) of the present invention is favorably a composition obtained through a refining step. A refining step like this is preferably filtration using a filter.

As this filtration using a filter, it is favorable to mix the polymerizable compound (a), the photopolymerization initiator (b), and the nonpolymerizable compound (c) described above, and filtrate the mixture by using, for example, a filter having a pore diameter of 0.001 μm or more and 5.0 μm or less. When performing filtration using a filter, is it further favorable to perform the filtration in multiple stages, or to repetitively perform the filtration a plurality of times (cycle filtration). It is also possible to re-filtrate a liquid once filtrated through a filter, or perform filtration by using filters having different pore diameters. Examples of the filter for use in filtration are filters made of, for example, a polyethylene resin, a polypropylene resin, a fluorine resin, and a nylon resin, but the filter is not particularly limited. Impurities such as particles mixed in the curable composition (A) can be removed through the refining step as described above. Consequently, it is possible to prevent impurities mixed in the curable composition (A) from causing pattern defects by forming unexpected unevenness on a cured film obtained after the curable composition (A) is cured.

Note that when using the curable composition (A) of the present invention in order to fabricate a semiconductor integrated circuit, it is favorable to avoid mixing of impurities (metal impurities) containing metal atoms in the curable composition (A) as much as possible so as not to obstruct the operation of a product. The concentration of the metal impurities contained in the curable composition (A) is preferably 10 ppm or less, and more preferably 100 ppb or less.

If a glass transition temperature is much higher than the temperature at the time of mold release, the cured product at the time of mold release exhibits a firm glass state, that is, a high mechanical strength, and therefore, pattern collapse or breakage due to impact of mold release hardly occurs. Hence, when executing the mold release step at room temperature, the glass transition temperature of the cured product of the nonvolatile composition (A′) is preferably 70° C. or more, more preferably 100° C. or more, and particularly preferably 150° C. or more.

As a method of measuring the glass transition temperature of the cured product (photocured product), a method of performing measurement using differential scanning calorimetry (DSC) or a dynamic viscoelasticity measuring apparatus can be applied. For example, consider a case where the glass transition temperature is measured using DSC. In this case, a line obtained by extending the baseline of the DSC curve of a cured product on the low temperature side (a DSC curve portion in a temperature region where neither transition nor reaction occurs in a test piece) to the high temperature side and a tangent drawn at a point where the gradient of the curve of the stepwise change portion of glass transition is maximum are obtained. From the intersection between the line and the tangent, an extrapolated glass transition start temperature (Tig) is obtained, and this can be obtained as the glass transition temperature. An example of a major apparatus is STA-6000 (manufactured by Perkin Eimer). On the other hand, when measuring the glass transition temperature using a dynamic viscoelasticity measuring apparatus, a temperature at which the loss sine (tan δ) of the cured product is maximum is defined as the glass transition temperature. An example of a major apparatus for measuring dynamic viscoelasticity is MCR301 (manufactured by Anton Paar).

In addition, as the curable composition (A), a composition having the same composition as the curable composition for imprint processing for manufacturing various kinds of devices, that is, device imprint may be used. If the curable composition (A) has the same composition as the curable composition for device imprint (the same curable composition is used), the same apparatus as an apparatus (imprint apparatus) for performing device imprint can be used in manufacturing of the replica mold RM.

### <Arranging Step>

In the arranging step, as schematically shown in FIG. 5B, droplets 102 of the curable composition (A) are discretely arranged on the master mold MM.

As an arranging method of arranging the droplets 102 of the curable composition (A) on the master mold MM, an inkjet method is particularly preferable. The droplets 102 of the curable composition (A) are densely arranged on a region where concave portions that form the fine pattern FP of the master mold MM densely exist, and coarsely arranged on a region where concave portions that form the fine pattern FP of the master mold MM coarsely exist. Hence, a residual film in the cured film of the curable composition (A) formed on the master mold MM is controlled to an even thickness regardless of whether the fine pattern FP of the master mold MM is dense or coarse.

### <Waiting Step>

The waiting step is provided after the arranging step and before the contact step (between the arranging step and the contact step). The waiting step is, for example, 0.1 sec to 600 sec, and preferably 10 sec to 300 sec.

In the waiting step, as schematically shown in FIGS. 5C and 5D, the droplets 102 of the curable composition (A) spread on the master mold MM, and the droplets combine with each other, and a practically continuous liquid film 103 is formed. The state of the curable composition (A) as shown in FIG. 5D is called “a practically continuous liquid film”. Note that if the curable composition (A) contains the solvent (d), in the waiting step, the solvent (d) contained in the liquid film 103 is volatilized, as schematically shown in FIG. 5E.

In the waiting step, it is possible to perform a baking step of heating the master mold MM and the curable composition (A), or ventilate the atmospheric gas around the master mold MM, for the purpose of accelerating the volatilization of the solvent (d). The heating is performed at, for example, 30° C. or more and 200° C. or less, preferably 80° C. or more and 150° C. or less, and particularly preferably 90° C. or more and 110° C. or less. The heating time can be 10 sec or more and 600 sec or less. The baking step can be performed by using a known heater such as a hotplate or an oven.

### <Contact Step>

In the contact step, as schematically shown in FIG. 5F, the practically continuous liquid film 103 of the curable composition (A) from which the solvent (d) is removed, that is, the nonvolatile composition (A′) on the master mold MM is brought into contact with a replica base material 101 (mesa portion 14) that is the high elastic modulus part 10. The contact step includes a step of a changing a state in which the nonvolatile composition (A′) on the master mold MM and the replica base material 101 are not in contact with each other to a state in which they are in contact with each other, and a step of maintaining the state in which they are in contact with each other.

The replica base material 101 preferably has a size of 152.4 mm (6 inches) square and a thickness of 6.35 mm (0.25 inches). Also, as the material of the replica base material 101, a high elastic modulus material having an elastic modulus of 50 GPa or more is preferable, more specifically, silica glass is preferable. Silica glass is available as a high-quality photomask base material in the semiconductor industry and has a high use result.

The contact step is preferably 0.1 sec or more and 600 sec or less, and particularly preferably 0.1 sec or more and 10 sec or less. If the contact step is shorter than 0.1 sec, contact between the nonvolatile composition (A′) on the master mold MM and the replica base material 101 may be insufficient.

In the contact step, the pressure to be applied to the nonvolatile composition (A′) when bringing the replica base material 101 into contact with the nonvolatile composition (A′) on the master mold MM is not particularly limited, and is, for example, 0 MPa or more and 100 MPa or less. Note that when bringing the replica base material 101 into contact with the nonvolatile composition (A′) on the master mold MM, the pressure to be applied to the nonvolatile composition (A′) is preferably 0 MPa or more and 50 MPa or less. Also, when bringing the replica base material 101 into contact with the nonvolatile composition (A′) on the master mold MM, the pressure to be applied to the nonvolatile composition (A′) is more preferably 0 MPa or more and 30 MPa or less, and further preferably 0 MPa or more and 20 MPa or less.

The contact step can be performed in any of a normal air atmosphere, a reduced-pressure atmosphere, and an inert-gas atmosphere. However, the reduced-pressure atmosphere or the inert-gas atmosphere is favorable because it is possible to prevent the influence of oxygen or water on the curing reaction. Practical examples of an inert gas to be used when performing the contact step in the inert-gas atmosphere are nitrogen, carbon dioxide, helium, argon, various freon gases, and gas mixtures thereof. When performing the contact step in a specific gas atmosphere including a normal air atmosphere, a favorable pressure is 0.0001 atm or more and 10 atm or less.

### <Curing Step>

In the curing step, as schematically shown in FIG. 5G, the liquid film 103 of the nonvolatile composition (A′) is cured by being irradiated with irradiation light 107 as curing energy, thereby forming a cured film. In the curing step, for example, the liquid film 103 of the nonvolatile composition (A′) is irradiated with the irradiation light 107 through the replica base material 101. More specifically, the nonvolatile composition (A′) filled in the fine pattern FP of the master mold MM is irradiated with the irradiation light 107 through the replica base material 101. Consequently, the nonvolatile composition (A′) filled in the fine pattern FP of the master mold MM is cured and forms a cured film 108 having the pattern.

The irradiation light 107 is selected in accordance with the sensitivity wavelength of the nonvolatile composition (A′). More specifically, the irradiation light 107 is properly selected from ultraviolet light, X-ray, and an electron beam each having a wavelength of 150 nm or more and 400 nm or less. Note that the irradiation light 107 is particularly preferably ultraviolet light. This is so because many compounds commercially available as curing assistants have sensitivity to ultraviolet light. Examples of a light source that emits ultraviolet light are a high-pressure mercury lamp, an ultrahigh-pressure mercury lamp, a low-pressure mercury lamp, a Deep-UV lamp, a carbon arc lamp, a chemical lamp, a metal halide lamp, a xenon lamp, a KrF excimer laser, an ArF excimer laser, and an F₂ laser. Note that the ultrahigh-pressure mercury lamp is particularly favorable as the light source for emitting ultraviolet light. It is possible to use one light source or a plurality of light sources.

Light can be emitted to the entire region of the nonvolatile composition (A′) filled in the fine pattern FP of the master mold MM, or to only a partial region thereof (by limiting the region). It is also possible to intermittently emit light to the entire region of the replica base material 101 (mesa portion 14) a plurality of times, or to continuously emit light to the entire region of the replica base material 101. Furthermore, a first region of the replica base material 101 can be irradiated with light in a first irradiation process, and a second region different from the first region of the replica base material 101 can be irradiated with light in the second irradiation process.

### <Mold Release Step>

In the mold release step, as schematically shown in FIG. 5H, the master mold MM is released from the cured film 108. By releasing the cured film 108 having a pattern and the master mold MM from each other, the cured film 108 having a pattern formed by inverting the fine pattern FP of the master mold MM is obtained in an independent state on the replica base material 101. Here, a film remains in the concave portions of the cured film 108 having the pattern corresponding to the fine pattern FP of the master mold MM. This film is called a residual film.

In this embodiment, the thickness of the residual film corresponds to the thickness of the base portion 312 defined by the distance between the third surface 31a and the fourth surface 31b of the base portion 312 (see FIG. 3), and is 0.1 μm or more and 10 μm or less. In other words, the cured film 108 (low elastic modulus part 31) is formed such that the thickness of the residual film (the thickness of the base portion 312 defined by the distance between the third surface 31a and the fourth surface 31b of the base portion 312) is 0.1 μm or more and 10 μm or less. When the thickness of the residual film is 10 μm or less, a distortion amount to exposure heat or a stamping force is less than several nm. Hence, the apparatus can be provided for semiconductor use for which an overlay accuracy or alignment accuracy of several nm is required. Also, the residual film preferably has a thickness about 10 times an assumed foreign substance. The thicker the residual film is, the higher the followability to a foreign substance in device imprint is. For example, if a foreign substance is assumed to have a height of 10 nm, which impairs stamping (contact between the curable composition (A) on the master mold and the replica base material 101), the residual film preferably has a thickness of 0.1 μm or more.

A method of releasing the master mold MM from the cured film 108 having the pattern can be any method provided that the method does not physically break a part of the cured film 108 having the pattern during the release, and various conditions and the like are not particularly limited. For example, it is possible to fix the replica base material 101 and move the master mold MM away from the replica base material 101. It is also possible to fix the master mold MM and move the replica base material 101 away from the master mold MM. Furthermore, the master mold MM can be released from the cured film 108 having the pattern by moving both the master mold MM and the replica base material 101 in exactly opposite directions.

The second step (deposition method) is a step of forming the inorganic film 32 that covers the low elastic modulus part 31, that is, the cured film 108 having a pattern, as described above, and includes a preparation step of the inorganic film 32, and a deposition step of the inorganic film 32.

### <Preparation Step of Inorganic Film>

As the inorganic film 32 that covers the cured film 108 that is the low elastic modulus part 31, at least one material selected from metals, semiconductors, ceramics, oxide-based ceramics, and glass or a compound thereof is used. The inorganic film 32 made of these materials impedes adhesion or bonding of the cured film 108 that is the low elastic modulus part 31 and (the liquid of) the curable composition for device imprint, and contributes to excellent separation performance. Also, when the cured film 108 that is the low elastic modulus part 31 is protected by the inorganic film 32, the durable life of the replica mold RM can be prolonged.

The metal is formed by a metal element such as Cr, Be, Wi, Cd, Ga, In, Ir, Mg, Mn, Mo, Os, Pa, Rh, Ru, Ta, Ti, V, Zn, Sn, Zr, Cu, Ni, Co, Fe, Pt, Ag, Au, Pb, W, Al, or Hf. Also, the metal may be formed by an oxide containing these elements.

The semiconductor material is formed by, for example, Si, Ge, α-Sn, Se, Te, B, GaP, GaAs, InP, InSb, InAs, GaSb, GaN, AlN, InN, ITO, AlxGa1-xAs, or InxGa1-xN. Also, the semiconductor material may be formed by an oxide containing these.

The ceramic is formed by, for example, a non-oxide-based ceramic (a carbide, a nitride, a boride, or a silicide), Si₃N₄, BN, SiC, or the like.

The oxide-based ceramic is formed by Al₂O₃, MgO, ZrO₂, TiO, Ti₂O₃, TiO₂, a suboxide, or the like.

The glass is formed by, for example, borosilicate glass, silica (SiO₂), or the like.

The inorganic film 32 is selected from the above-described materials. SiO₂, Al₂O₃, and HfO₂ are preferable, and SiO₂ is particularly preferable. However, the inorganic film 32 may be made of a material other than the above-described materials. In this case, the material forming the inorganic film 32 is preferably a transparent material or a material close to transparent. In addition, the material forming the inorganic film 32 preferably has conductivity. Furthermore, the material forming the inorganic film 32 is preferably conductive and transparent.

### <Deposition Step of Inorganic Film>

In the deposition step of the inorganic film 32, the above-described material is deposited to form the inorganic film 32 such that the cured film 108 that is the low elastic modulus part 31 is covered. Examples of the preferable deposition method are sputtering, chemical vapor deposition (CVD), and atomic layer deposition (ALD). In this embodiment, CVD includes plasma enhanced chemical vapor deposition (PECVD). Also, CVD includes atmospheric pressure plasma CVD. Atmospheric pressure plasma CVD includes atmospheric pressure plasma jet (APP-Jet) and atmospheric pressure dielectric barrier discharge (AP-DBD) processes. Note that APP-Jet is short for atmospheric pressure plasma jet. AP-DBD is short for atmospheric pressure dielectric barrier discharge.

A manufacturing method of manufacturing the replica mold RM, more specifically, the second step of forming the inorganic film 32 will be described below with reference to FIGS. 6A and 6B. As shown in FIG. 6A, using the above-described deposition method, the material (constituent substance) of the inorganic film 32 is deposited on the surface of the cured film 108 (low elastic modulus part 31) formed on the replica base material 101 (mesa portion 14). By continuing this process for a predetermined time, as shown in FIG. 6B, for example, the inorganic film 32 having a thickness of 10 nm or less is formed. The thickness of the inorganic film 32 is, for example, 10 nm or less, preferably 1 nm or more and 10 nm or less, and particularly preferably 1 nm or more and 5 nm or less. If the thickness of the inorganic film 32 is 1 nm or less, it is impossible to obtain sufficient performance for protecting the replica mold RM (low elastic modulus part 31). If the thickness of the inorganic film 32 is 10 nm or more, it is difficult to micronize the pattern of the replica mold RM.

Conventionally, a replica mold is repetitively used, and if the pattern portion 314 (cured film 108) is worn, it is discarded together with the replica base material 101. On the other hand, in the replica mold RM, the cured film 108 and the inorganic film 32 formed on the replica base material 101 can be removed by cleaning. In other words, in the replica mold RM, the cured film 108, that is, the pattern portion 314 can selectively be removed together with the inorganic film 32 without damaging the replica base material 101. Hence, the cured film 108 can be formed again on the replica base material 101 after removal of the cured film 108 and the inorganic film 32, and the inorganic film 32 that covers the cured film 108 can further be formed. Removal of the cured film 108 and the inorganic film 32, formation of the cured film 108, and formation of the inorganic film 32 are thus repeated for the replica base material 101. This makes it possible reuse the expensive replica base material 101 and reduce the manufacturing cost of the replica mold RM.

The thus manufactured replica mold RM is used for, for example, imprint processing for manufacturing various kinds of devices, that is, device imprint. Here, the replica mold RM has a structure in which the cured film 108 (low elastic modulus part 31) and the inorganic film 32 that covers the cured film 108 are formed on the replica base material 101 (high elastic modulus part 10), as described above. Hence, the replica mold RM can reduce the noncontact region and suppress adhesion of the curable composition to the replica mold RM in device imprint.

### [Imprint Method]

A film forming method according to one aspect of the present invention will be described. In this embodiment, the film forming method is executed as imprint processing (imprint method) using a replica mold by forming a film of a curable composition in a space between the replica mold and a substrate. Also, imprint processing is executed as a pattern forming method of forming a film having a pattern.

### EXAMPLES

To supplement the above-described embodiment, more detailed examples will be described.

### <Deformation Analysis of Foreign Substance Following>

It was confirmed, by a method to be described below, that the foreign substance followability of a replica mold according to Example 1 (the replica mold RM according to this embodiment) was superior to the foreign substance followability of replica molds according to Comparative Examples 1, 2, 3, and 4.

### (1-1) Manufacturing of Replica Mold

Replica molds were manufactured as Example 1 and Comparative Examples 1, 3, and 4 such that these had configurations shown in Table 1 below.

### Example 1

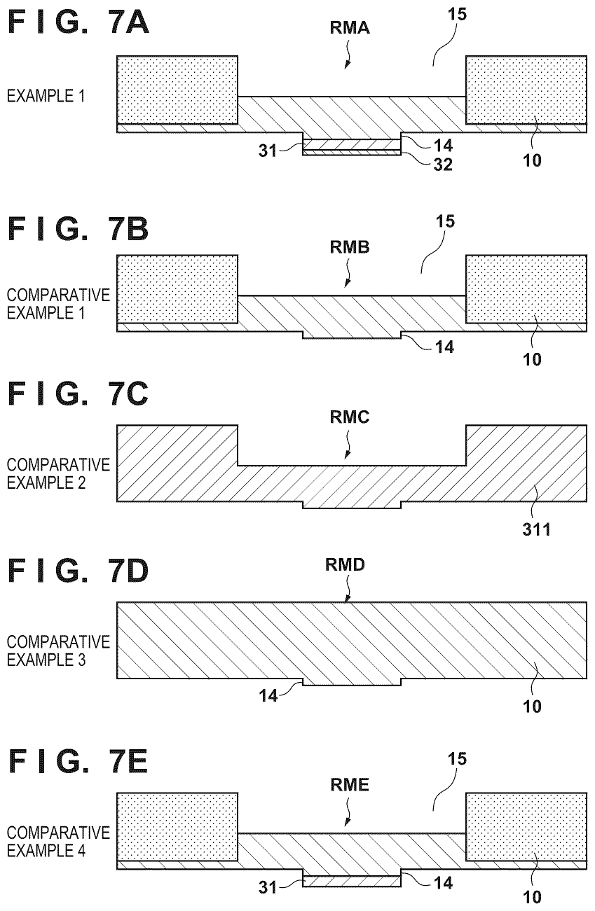

As Example 1, a replica mold RMA shown in FIG. 7A is manufactured. The replica mold RMA includes a high elastic modulus part 10, a low elastic modulus part 31, and an inorganic film 32.

A high elastic modulus part 10 that is a replica base material has a size of 152.4 mm square and a thickness of 6.35 mm. A mesa portion 14 having a height of 30 μm and an area of 26 mm×33 mm is provided at the center portion (pattern region 13) of a first surface 11. A second surface 12 of the high elastic modulus part 10 has a circular concave portion 15 (core out) with a diameter of 60 mm, which overlaps the mesa portion 14 (pattern region 13) and has an area larger than that of the mesa portion 14. The thickness of the portion of the concave portion 15 of the high elastic modulus part 10 is 1 mm. The high elastic modulus part 10 is made of synthetic silica glass having an elastic modulus of about 72 GPa.

To improve the adhesion to the low elastic modulus part 31 (curable composition (A)), acryloxypropyltrimethoxysilane that is an acrylic group-containing silane coupling agent is vapor-deposited on the mesa portion 14 of the high elastic modulus part 10.

As a master mold MM, a mold that is made of a silicon wafer with a diameter of 300 mm and has a fine pattern FP formed at the center portion of a region of 26 mm×33 mm is prepared.

The curable composition (A) is dropped by an inkjet method to the portion of the fine pattern FP of the master mold MM such that the thickness of a residual film is 10 μm, thereby forming a liquid film.

The mesa portion 14 (pattern region 13) of the high elastic modulus part 10 that is the replica base material is brought into contact with the liquid film of a nonvolatile composition (A′) obtained by volatilizing a solvent (d) from the curable composition (A) on the master mold MM. Then, the nonvolatile composition (A′) is irradiated with ultraviolet light through the high elastic modulus part 10 and thus cured. Accordingly, a low elastic modulus part 31 having a film thickness of 10 μm is formed on the mesa portion 14 of the high elastic modulus part 10. The elastic modulus of the low elastic modulus part 31 is about 3 GPa.

SiO₂ is deposited to a thickness of 5 nm on the surface of the low elastic modulus part 31 formed on the mesa portion 14 of the high elastic modulus part 10 using ALD as a deposition method, thereby forming an inorganic film 32 that covers the low elastic modulus part 31.

### Comparative Example 1

A replica mold RMB shown in FIG. 7B is manufactured as Comparative Example 1. The replica mold RMB does not include a low elastic modulus part 31 and an inorganic film 32. Synthetic silica glass having the same structure as in Example 1 is prepared as a high elastic modulus part 10 that is a replica base material. A fine pattern is formed by an electron beam lithography technique on a mesa portion 14 of a high elastic modulus part 10.

### Comparative Example 2

A replica mold RMC shown in FIG. 7C is manufactured as Comparative Example 2. The replica mold RMC does not include a high elastic modulus part 10 and an inorganic film 32. The replica mold RMC uses, as a replica base material, a low elastic modulus part 311 made of polycarbonate having the same structure as the high elastic modulus part 10. The low elastic modulus part 311 has an elastic modulus of about 3 GPa. A fine pattern is formed by an electron beam lithography technique on the mesa portion of the low elastic modulus part 311.

### Comparative Example 3

A replica mold RMD shown in FIG. 7D is manufactured as Comparative Example 3. The replica mold RMD does not include a low elastic modulus part 31 and an inorganic film 32. A high elastic modulus part 10 that is a replica base material has a size of 152.4 mm square and a thickness of 6.35 mm, and a mesa portion 14 having a height of 30 μm and an area of 26 mm×33 mm is provided at the center portion (pattern region 13) of a first surface 11. A second surface 12 of the high elastic modulus part 10 does not include the concave portion 15. A fine pattern is formed by an electron beam lithography technique on the mesa portion 14 of the high elastic modulus part 10.

### Comparative Example 4

A replica mold RME shown in FIG. 7E is manufactured as Comparative Example 4. The replica mold RME does not include an inorganic film 32. As a high elastic modulus part 10 that is a replica base material, synthetic silica glass having the same structure as in Example 1 is prepared. Like Example 1, a curable composition (A) is dropped by an inkjet method to the portion of a fine pattern FP of a master mold MM, thereby forming a liquid film. A mesa portion 14 (pattern region 13) of a high elastic modulus part 10 that is the replica base material is brought into contact with the liquid film of a nonvolatile composition (A′) obtained by volatilizing a solvent (d) from the curable composition (A) on the master mold MM. Then, the nonvolatile composition (A′) is irradiated with ultraviolet light through the high elastic modulus part 10 and thus cured. Accordingly, a low elastic modulus part 31 is formed on the mesa portion 14 of the high elastic modulus part 10. A fine pattern is formed by an electron beam lithography technique on the low elastic modulus part 31 formed on the mesa portion 14 of the high elastic modulus part 10.

TABLE 1

| | Replica base | | |
|---|---|---|---|
| | material + mesa | | |
| | portion | Pattern portion | Inorganic film |
| Example 1 | synthetic silica | nonvolatile | present |
| | glass (with | composition (A′) | |
| | concave portion) | | |
| Comparative | synthetic silica | synthetic silica | absent |
| example 1 | glass (with | glass | |
| | concave portion) | | |
| Comparative | polycarbonate | polycarbonate | absent |
| example 2 | (without concave | | |
| | portion) | | |
| Comparative | synthetic silica | synthetic silica | absent |
| example 3 | glass (without | glass | |
| | concave portion) | | |
| Comparative | synthetic silica | nonvolatile | absent |
| example 4 | glass (with | composition (A′) | |
| | concave portion) | | |

### (1-2) Device Imprint

Imprint processing for manufacturing various kinds of devices, that is, device imprint is performed using the replica molds RMA (Example 1), RMB (Comparative Example 1), RMC (Comparative Example 2), RMD (Comparative Example 3), and RMC (Comparative Example 4). The imprint processing includes, for example, an arranging step, a waiting step, a contact step, a curing step, and a mold release step. The arranging step is a step of discretely arranging droplets of a curable composition for device imprint on a device substrate. The waiting step is a step of waiting until the droplets of the curable composition for device imprint combine with each other. The contact step is a step of bringing the curable composition for device imprint into contact with the replica mold. The curing step is a step of curing the curable composition for device imprint. The mold release step is a step of releasing the replica mold from the cured film of the curable composition for device imprint. The waiting step is executed after the arranging step, the contact step is executed after the waiting step, the curing step is executed after the contact step, and the mold release step is executed after the curing step.

As the device substrate, a silicon wafer having a diameter of 300 mm is prepared. The curable composition for device imprint is dropped by the inkjet method to form a liquid film on one shot region (one field) of the silicon wafer (the arranging step and the waiting step).

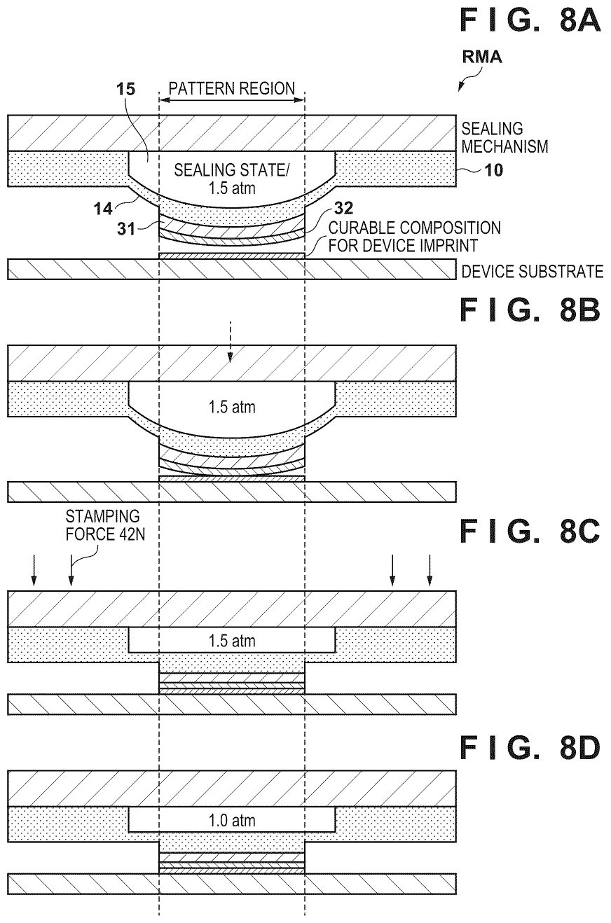

In the contact step, as schematically shown in FIG. 8A, the concave portion 15 of the replica mold RMA is sealed to form a sealed space, a nitrogen gas is supplied to the sealed space, and the pressure in the sealed space is set to 1.5 atm. Thus, the concave portion 15 is deflected to curve (deform) (the mesa portion 14 of) the replica mold RMA (and the low elastic modulus part 31 and the inorganic film 32 formed on the mesa portion 14) into a convex shape to the side of the device substrate. Note that as a sealing mechanism configured to change the concave portion 15 to the sealed space, for example, a holding unit that holds the replica mold RMA can be used. The holding unit may include a seal member such as a seal glass used to change the concave portion 15 to the sealed space. Next, as schematically shown in FIG. 8B, the replica mold RMA is lowered in a state in which it is curved, and only the center portion of the mesa portion 14 and the low elastic modulus part 31 and the inorganic film 32 formed on the mesa portion 14 is brought into contact with the curable composition on the device substrate. Also, as schematically shown in FIG. 8C, while applying a stamping force of 42 N at maximum, the replica mold RMA is sequentially brought into contact with the curable composition on the device substrate from the center portion of the replica mold RMA to the outer peripheral portion.

As described above, in the contact step, the concave portion 15 of the high elastic modulus part 10 is deflected, thereby bringing the center portion of the low elastic modulus part 31 and the inorganic film 32 into contact with the liquid film of the curable composition on the device substrate. Then, as schematically shown in FIG. 8D, after the center portion of the low elastic modulus part 31 and the inorganic film 32 is brought into contact with the liquid film of the curable composition, the deflection of the concave portion 15 is canceled, thereby bringing the whole surface of the low elastic modulus part 31 and the inorganic film 32 into contact with the liquid film of the curable composition on the device substrate.

In the curing step, the curable composition on the device substrate is irradiated with ultraviolet light as curing energy through the replica mold RMA and thus cured.

In the mold release step, the replica mold RMA is released from the cured film of the curable composition on the device substrate. Thus, a cured film having a pattern obtained by inverting the pattern of the replica mold RMA is formed on the device substrate.

Device imprint has been described with reference to FIGS. 8A to 8D using the replica mold RMA as an example. Device imprint using each of the replica molds RMB, RMC, RMD, and RME is similarly performed. However, the replica mold RMD does not include the concave portion 15 and is therefore brought into contact with the curable composition on the device substrate without being curved.

### (Analysis of Behavior of Following Foreign Substance)

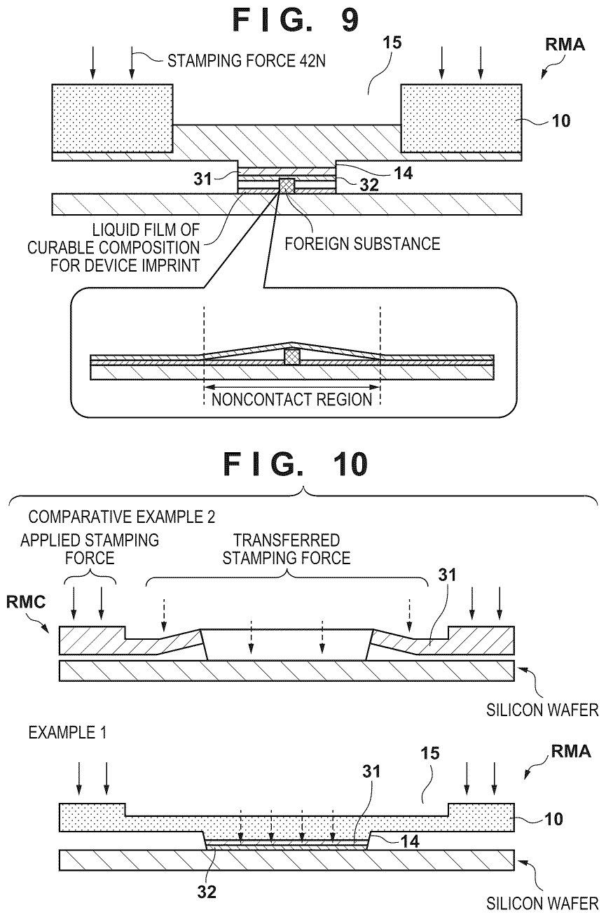

An analysis model of the behavior of the replica mold of following a foreign substance existing on the device substrate will be described with reference to FIG. 9. A liquid film of a curable composition having an average thickness of 50 nm is formed in a 26 mm×33 mm shot region of a silicon wafer that serves as a device substrate and has a diameter of 300 mm and an elastic modulus of 190 GPa. Assume that a columnar foreign substance having a diameter of 1 μm and a height of 1 μm exists at the center portion of the liquid film on the shot region of the device substrate. In a case where the replica mold was brought into contact with the shot region at a stamping force of 42 N, the following behavior (deformation) of each of the replica molds according to Example 1 and Comparative Examples 1 and 2 was analyzed. A meniscus pressure caused by the liquid film sandwiched between the replica mold and the silicon wafer was calculated as 1.18 MPa. Since the replica mold was attracted to the side of the silicon wafer by the meniscus pressure, the influence was also taken into consideration. In the analysis model, the radius of a noncontact region generated between the replica mold and the silicon wafer due to the sandwiched foreign substance was calculated. It is determined that the smaller the radius of the noncontact region is, the higher the followability to the foreign substance is. For the analysis, finite element analysis software Abaqus available from Dassault Systemes was used.

For Example 1, device imprint (stamping) could be performed without sandwiching the atmospheric gas between the replica mold RMA and the silicon wafer. The radius of the noncontact region formed around the foreign substance was 16 μm.

For Comparative Example 1, device imprint (stamping) could be performed without sandwiching the atmospheric gas between the replica mold RMB and the silicon wafer. The radius of the noncontact region formed around the foreign substance was 54 μm.

For Comparative Example 2, device imprint (stamping) could be performed without sandwiching the atmospheric gas between the replica mold RMC and the silicon wafer. The radius of the noncontact region formed around the foreign substance was 22 μm.

The difference of the behavior of the replica mold of following a foreign substance between Example 1 and Comparative Example 2 will be described here with reference to FIG. 10. In Comparative Example 2, since the whole replica mold RMC is made of a low elastic modulus material having an elastic modulus of about 3 GPa, the stamping force is consumed to deform the concave portion of the replica mold RMC. On the other hand, in Example 1, since the concave portion 15 (replica base material) of the replica mold RMA is made of a high elastic modulus material having an elastic modulus of about 72 GPa, the stamping force consumed to deform the concave portion 15 is small, and the stamping force is transmitted to the mesa portion 14. Hence, in the low elastic modulus part 31 and the inorganic film 32 formed on the mesa portion 14 of the replica mold RMA, the behavior of following a foreign substance is improved, as compared to Comparative Example 2.

For Comparative Example 3, in device imprint (stamping), the atmospheric gas was sandwiched between the replica mold RMD and the silicon wafer. This is because synthetic silica glass having a thickness of 6.35 mm cannot be curved at 1.5 atm. Analysis of the behavior of following a foreign substance was not conducted.

For Comparative Example 4, irradiation of ultraviolet rays is performed in device imprint (stamping), thereby combing the low elastic modulus part 31 and the curable composition for device imprint. This poses a problem that the low elastic modulus part 31 is peeled from the high elastic modulus part 10, or the curable composition for device imprint is peeled from the device substrate. Analysis of behavior of following a foreign substance was not executed.

### <Deformation Analysis of Heat/Stress Distortion>

It was confirmed, by a method to be described below, that the resistance of the replica molds of Examples 1 and 2 (the replica mold RM according to this embodiment) to thermal deformation was superior to the resistance of the replica molds of Comparative Examples 1, 2, 3, and 4 to thermal deformation.

### (2-1) Manufacturing of Replica Mold

Replica molds were manufactured as Example 1 and 2 and Comparative Examples 1, 3, and 4 such that these had configurations shown in Table 2 below.

### Examples 1 and 2 and Comparative Examples 2 and 3

In Examples 1 and 2 and Comparative Examples 2 and 3, a high elastic modulus part 10 that is a replica base material has a size of 152.4 mm square and a thickness of 6.35 mm. A mesa portion 14 having a height of 30 μm and an area of 26 mm×33 mm is provided at the center portion (pattern region 13) of a first surface 11. A second surface 12 of the high elastic modulus part 10 has a circular concave portion 15 (core out) with a diameter of 60 mm, which overlaps the mesa portion 14 (pattern region 13) and has an area larger than that of the mesa portion 14. The thickness of the portion of the concave portion 15 of the high elastic modulus part 10 is 1 mm. The high elastic modulus part 10 is made of synthetic silica glass having an elastic modulus of about 72 GPa.

To improve the adhesion to the low elastic modulus part 31 (curable composition (A)), acryloxypropyltrimethoxysilane that is an acrylic group-containing silane coupling agent is vapor-deposited on the mesa portion 14 of the high elastic modulus part 10.

As a master mold MM, a mold that is made of a silicon wafer with a diameter of 300 mm and has a fine pattern FP formed at the center portion of a region of 26 mm×33 mm is prepared. The curable composition (A) is dropped by an inkjet method to the portion of the fine pattern FP of the master mold MM such that the thickness of a residual film is 10 μm in Example 1, and the thickness of a residual film is 20 μm in Example 2, thereby forming a liquid film. The curable composition (A) is dropped by an inkjet method to the portion of the fine pattern FP of the master mold MM such that the thickness of a residual film is 30 μm in Comparative Example 2, and the thickness of a residual film is 100 μm in Comparative Example 3, thereby forming a liquid film.

The mesa portion 14 (pattern region 13) of the high elastic modulus part 10 that is the replica base material is brought into contact with the liquid film of a nonvolatile composition (A′) obtained by volatilizing a solvent (d) from the curable composition (A) on the master mold MM. Then, the nonvolatile composition (A′) is irradiated with ultraviolet light through the high elastic modulus part 10 and thus cured. Accordingly, a low elastic modulus part 31 having various film thicknesses is formed on the mesa portion 14 of the high elastic modulus part 10. The elastic modulus of the low elastic modulus part 31 is about 3 GPa.

SiO₂ is deposited in a thickness of 5 nm on the surface of the low elastic modulus part 31 formed on the mesa portion 14 of the high elastic modulus part 10 using ALD as a deposition method, thereby forming an inorganic film 32 that covers the low elastic modulus part 31.

### Comparative Example 1

As Comparative Example 1, a replica mold that does not include a low elastic modulus part 31 and an inorganic film 32 is manufactured. Synthetic silica glass having the same structure as in Example 1 is prepared as a high elastic modulus part 10 that is a replica base material.

### Comparative Example 4

As Comparative Example 4, a replica mold that does not include a high elastic modulus part 10 and an inorganic film 32 is manufactured. In Comparative Example 4, polycarbonate having the same structure as the high elastic modulus part 10 is used as a replica base material. The polycarbonate has an elastic modulus of about 3 GPa.

### (2-2) Analysis of Deformation Behavior to Heat

To evaluate deformation of (the pattern of) a replica mold by irradiation heat (exposure heat) of ultraviolet rays, thermal deformation of a replica mold when the irradiation energy was 10,000 W/m² and the irradiation time was 0.1 sec, which were general conditions in device imprint, was analyzed. If the deformation amount of the replica mold was 1 nm or less, it was evaluated as satisfactory (◯). If the deformation amount of the replica mold was larger than 1 nm and 5 nm or less, it was evaluated as permissible (Δ). If the deformation amount of the replica mold was larger than 5 nm, it was evaluated as impermissible (x).

TABLE 2

| | Replica base | | | |
|---|---|---|---|---|
| | material + | Pattern | Film | Thermal |
| | mesa portion | portion | thickness | deformation |
| Comparative | synthetic | absent | — | ∘ |
| example 1 | silica glass | | | |
| Example 1 | synthetic | nonvolatile | 10 μm | ∘ |
| | silica glass | composition | | |
| | | (A′) | | |
| Example 2 | synthetic | nonvolatile | 20 μm | ∘ |
| | silica glass | composition | | |
| | | (A′) | | |
| Comparative | synthetic | nonvolatile | 30 μm | Δ |
| example 2 | silica glass | composition | | |
| | | (A′) | | |
| Comparative | synthetic | nonvolatile | 100 μm | Δ |
| example 3 | silica glass | composition | | |
| | | (A′) | | |
| Comparative | polycarbonate | absent | — | x |
| example 4 | | | | |

In each of Examples 1 and 2, since the replica mold was restricted by synthetic silica glass as the replica base material, the deformation amount was the same as in Comparative Example 1 as a conventional replica mold.

In each of Comparative Examples 2 and 3, although the replica mold was restricted by synthetic silica glass as the replica base material, the deformation amount was not durable against semiconductor use because the residual film was thick.

In Comparative Example 4, since the replica base material was not synthetic silica glass but polycarbonate, the deformation amount was large as compared to other examples and comparative examples.

As described above, according to this embodiment, it is possible to provide a replica mold with improved followability to a foreign substance. Hence, even if a foreign substance exists on a substrate, the noncontact region where the curable composition on the substrate and the replica mold are not in contact is reduced, and the transfer pattern of the replica mold can accurately be transferred. In addition, since it is unnecessary to apply a large stamping force to the replica mold, the possibility that the transfer pattern of the replica mold is compressed by the foreign substance and broken can be reduced. Also, in this embodiment, since the inorganic film that covers the low elastic modulus part of the replica mold is formed, it is possible to suppress adhesion of the curable composition to the replica mold.

### [Imprint Apparatus]

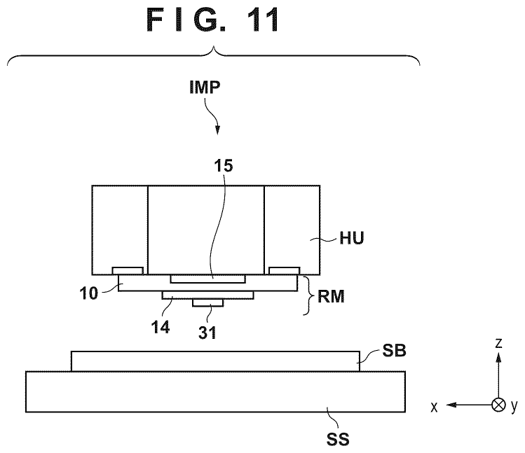

FIG. 11 is a schematic view illustrating the configuration of an imprint apparatus IMP according to an aspect of the present invention. The imprint apparatus IMP is a lithography apparatus that forms a pattern on a substrate. The imprint apparatus IMP brings a curable composition (imprint material) arranged on a substrate into contact with a replica mold, and applying curing energy to the curable composition, thereby forming a pattern of a cured product to which the pattern of the replica mold is transferred.

The imprint apparatus IMP includes a holding unit HU that holds a replica mold RM, and a substrate stage SS that holds a substrate SB. The imprint apparatus IMP also includes a supply unit including a dispenser configured to arrange (supply) a curable composition on the substrate, a bridge surface plate configured to hold the holding unit HU, and a base surface plate configured to hold the substrate stage SS.

The replica mold RM is a mold that forms the curable composition on the substrate. As described above, the replica mold RM includes a high elastic modulus part 10 including a mesa portion 14 and a concave portion 15, a low elastic modulus part 31 combined to (formed on) the mesa portion 14, and an inorganic film 32 that covers the low elastic modulus part 31.

The holding unit HU is a holding mechanism that holds the replica mold RM. The holding unit HU includes, for example, a chuck that vacuum-sucks or electrostatically attracts the replica mold RM, and a mold driving unit that drives the chuck. The mold driving unit drives (moves) the chuck sucking the replica mold RM, that is, the replica mold RM in the X direction, the Y direction, the Z direction, and the θZ direction.

The substrate stage SS is a holding mechanism that holds the substrate SB to which the transfer pattern of the replica mold RM is transferred. The substrate stage SS, for example, vacuum-sucks or electrostatically attracts the substrate SB via the chuck, and is driven by a substrate driving unit. The substrate driving unit drives the substrate stage SS holding the substrate SB, that is, the substrate SB in the X direction, the Y direction, the Z direction, and the θZ direction.

In the imprint apparatus IMP, in a state in which the curable composition on the substrate and the replica mold RM are in contact, ultraviolet light for curing the curable composition is emitted from the upper side of the apparatus. The curable composition on the substrate is thus cured. After that, when the replica mold RM is released, a cured film (cured product) of the curable composition to which the transfer pattern of the replica mold RM is transferred is formed on the substrate.

The pattern of a cured product formed using the imprint apparatus IMP is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, a SRAM, a flash memory, and a MRAM and semiconductor elements such as an LSI, a CCD, an image sensor, and an FPGA. Examples of the mold are molds for imprint. Examples of the optical element are light extraction structures such as a quantum dot structure, a sub-wavelength antireflection structure, and an LED, a photonic crystal, a wire grid polarizing plate for UV region, a structural birefringent wavelength plate, a diffraction grating, and a metalens.

The pattern of the cured product is directly used as the constituent member of at least some of the above-described articles or used temporarily as a resist mask. After etching or ion implantation is performed in the substrate processing step, the resist mask is removed.

### [Article Manufacturing Method]

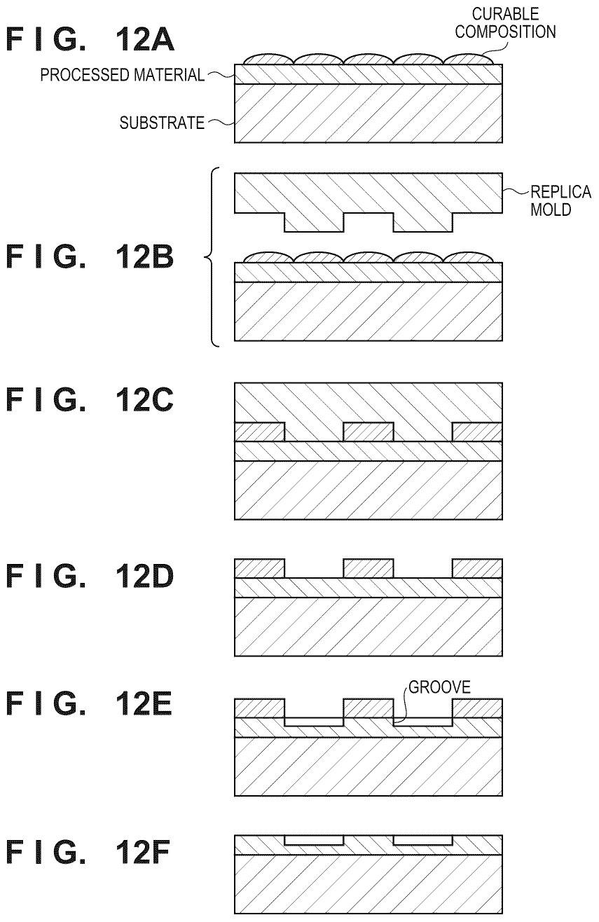

Description regarding a detailed method of manufacturing an article is given. As illustrated in FIG. 12A, the substrate such as a silicon wafer with a processed material such as an insulator formed on the surface is prepared. Next, a curable composition is applied to the surface of the processed material by an inkjet method or the like. A state in which the curable composition is applied as a plurality of droplets onto the substrate is shown here.

As shown in FIG. 12B, a side of the replica mold with a projection and groove pattern is formed on and caused to face the curable composition on the substrate. As illustrated in FIG. 12C, the substrate to which the curable composition is applied is brought into contact with the replica mold, and a pressure is applied. The gap between the replica mold and the processed material is filled with the curable composition. In this state, when the curable composition is irradiated with light serving as curing energy through the replica mold, the curable composition is cured.

As shown in FIG. 12D, after the curable composition is cured, the replica mold is released from the substrate. Thus, the pattern of the cured product of the curable composition is formed on the substrate. In the pattern of the cured product, the groove of the replica mold corresponds to the projection of the cured product, and the projection of the replica mold corresponds to the groove of the cured product. That is, the projection and groove pattern of the replica mold is transferred to the curable composition.

As shown in FIG. 12E, when etching is performed using the pattern of the cured product as an etching resistant mask, a portion of the surface of the processed material where the cured product does not exist or remains thin is removed to form a groove. As shown in FIG. 12F, when the pattern of the cured product is removed, an article with the grooves formed in the surface of the processed material can be obtained. The pattern of the cured material is removed here, but, for example, the pattern may be used as a film for insulation between layers included in a semiconductor element or the like without being removed after processing, in other words as a constituent member of the article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent application No. 2024-062921 filed on Apr. 9, 2024, which is hereby incorporated by reference herein in its entirety.

What is claimed is:

1. A mold including a first part made of a material having a first elastic modulus, and a second part made of a material having a second elastic modulus lower than the first elastic modulus, and used for imprint lithography,
wherein the first part includes a first surface including a mesa portion protruding from a plane, and a second surface on an opposite side of the first surface, which includes a concave portion,
the second part includes a base portion including a third surface combined to the mesa portion and a fourth surface on an opposite side of the third surface, and a pattern portion that includes a convex portion protruding from the fourth surface and defines a pattern,
a thickness of the base portion defined by a distance between the third surface and the fourth surface is not less than 0.1 μm and not more than 10 μm, and
the mold includes an inorganic film that covers the fourth surface of the base portion and the convex portion of the pattern portion.

2. The mold according to claim 1, wherein the inorganic film contains at least one material selected from the group consisting of metals, semiconductors, ceramics, oxide-based ceramics, and glass.

3. The mold according to claim 1, wherein the mesa portion is located in a region inside an outer edge of a region formed by orthogonally projecting the concave portion to a virtual plane parallel to the plane.

4. The mold according to claim 1, wherein
the first elastic modulus is not less than 20 GPa, and
the second elastic modulus is not more than 10 GPa.

5. The mold according to claim 1, wherein a distance between the plane of the first surface and a surface of a portion of the second surface where the concave portion does not exist is 6.35 mm±0.10 mm.

6. The mold according to claim 1, wherein a distance between the plane of the first surface and a bottom portion of the concave portion is not less than 0.1 mm and not more than 3 mm.

7. The mold according to claim 1, wherein the mesa portion has a height larger than 0 μm and not more than 1,000 μm.

8. The mold according to claim 1, wherein
the material having the second elastic modulus is formed by a curable composition containing a polymerizable compound, a photopolymerization initiator, and a solvent,
the curable composition has a viscosity of not less than 2 mPa·s and not more than 60 mPa·s at 23° C. and at 1 atm,
a content of the solvent to the whole curable composition is more than 5 vol % and not more than 95 vol %,
a boiling point of the solvent is less than 250° C. at 1 atm, and
a composition obtained by removing the solvent from the curable composition has a viscosity of not less than 20 mPa·s and not more than 10,000 mPa·s at 23° C. and at 1 atm.

9. The mold according to claim 1, wherein the mold includes a replica mold.

10. A manufacturing method of manufacturing a mold including a first part made of a material having a first elastic modulus, a second part made of a material having a second elastic modulus lower than the first elastic modulus, and an inorganic film, comprising:
forming, using an imprint method, on a mesa portion of the first part including a first surface including the mesa portion protruding from a plane, and a second surface on an opposite side of the first surface, which includes a concave portion, the second part including a base portion including a third surface combined to the mesa portion and a fourth surface on an opposite side of the third surface, and a pattern portion that includes a convex portion protruding from the fourth surface and defines a pattern; and
forming, using a deposition method, the inorganic film that covers the fourth surface of the base portion and the convex portion of the pattern portion,
wherein in the forming the second part, the second part is formed such that a thickness of the base portion defined by a distance between the third surface and the fourth surface is not less than 0.1 μm and not more than 10 μm.

11. The method according to claim 10, wherein the inorganic film contains at least one material selected from the group consisting of metals, semiconductors, ceramics, oxide-based ceramics, and glass.

12. The method according to claim 10, wherein the inorganic film contains one of Al₂O₃, SiO₂, and HfO₂.

13. The method according to claim 10, wherein the deposition method includes atomic layer deposition.

14. The method according to claim 10, further comprising:
removing the inorganic film and the second part;
after the removing, forming the second part on the mesa portion using the imprint method;
after the forming the second part, using the deposition method, forming the inorganic film that covers the fourth surface of the base portion and the convex portion of the pattern portion,
wherein in the forming the inorganic film, the second part is formed such that the thickness of the base portion defined by the distance between the third surface and the fourth surface is not less than 0.1 μm and not more than 10 μm.

15. The method according to claim 14, wherein the removing, the forming the second part, and the forming the inorganic film are repeated.

16. A film forming method of forming, using a mold defined in claim 1, a film of a curable composition in a space between the mold and a substrate, comprising:
discretely arranging a plurality of droplets of the curable composition on the substrate;
waiting until the plurality of droplets combine with adjacent droplets to form a liquid film; and
after the waiting, bringing the mold and the liquid film into contact with each other,
wherein in the bringing the mold and the liquid film into contact with each other, a center portion of a pattern portion of a second part of the mold is brought into contact with the liquid film by deflecting a concave portion of a second surface of a first part of the mold, and after the pattern portion is brought into contact with the liquid film, a whole surface of the pattern portion is brought into contact with the liquid film by canceling deflection of the concave portion.

17. An article manufacturing method comprising:
forming a film of a curable composition on a substrate using a film forming method defined in claim 16;
processing the substrate on which the film is formed in the forming; and
manufacturing an article from the substrate processed in the processing.

18. An imprint apparatus for forming a pattern of a curable composition on a substrate, comprising
a holding unit configured to hold a mold defined in claim 1.
